(19) United States
(12) Patent Application Publication
(10) Pub. No.: US 2012/0133448 A1
(43) Pub. Date: May 31, 2012

(54) MECHANICAL OSCILLATOR

(76) Inventors: John Francis Gregg, Oxford (GB); Alexy Davison Karenowska, Oxford (GB)

(21) Appl. No.: 13/144,886

(22) PCT Filed: Jan. 18, 2010
(86) PCT No.: PCT/GB10/00061

§ 371 Date: Sep. 13, 2011

(30) Foreign Application Priority Data
Jan. 16, 2009 (GB) 0900747.7

(51) Int. Cl. H03B 5/36

(52) U.S. Cl. 331/116 R

(57) ABSTRACT

A mechanical oscillator arrangement includes a mechanical structure (30) having at least one transmission path through it, and at least one mode. A controller (40) is provided with an amplifier (70) and a feedback network (80, 90) which together provide a positive feedback oscillator for exciting a mode of the mechanical structure (30). The feedback network (80, 90) comprises a non linear amplitude control element (N-LACE) (90), a frequency dependent gain element with an electronic transfer function, and a phase compensator (80). The mechanical oscillator arrangement also includes an actuator (606) which excites the mechanical structure (30) based upon an output from the controller (40), and a sensor (60a) which senses vibrations in the mechanical structure (30) and then outputs a signal to the controller (40) based upon the sensed vibrations. Such a stabilized positive feedback arrangement is self exciting at the effective resonance frequency of the mechanical structure and avoids the need for an external fixed or variable frequency driver.

### FIELD OF THE INVENTION

This invention relates to a mechanical oscillator device.

### BACKGROUND OF THE INVENTION

Mechanical resonances have been exploited for many decades in applications ranging from music-making to industrial demolition. Relatively recently, renewed interest in mechanical oscillators—instruments designed specifically for the excitation and maintenance of mechanical resonances—has been catalysed by the emergence of new applications in micro and nanoscale mechanical automation, information processing, and certain types of scanning microscopy and spectroscopy.

Despite the considerable technological progress of the last three decades, fundamental advances in the design of mechanical oscillator systems have been relatively limited: negative-feedback controllers of the type developed in the late 1970s—see for example U.S. Pat. No. 4,177,434—and quasi-positive feedback control-loop oscillators remain the prevalent technologies. Although adequate in many contexts, these arrangements have certain fundamental limitations which present significant technological obstacles in the most demanding applications. Negative-feedback type controllers are plagued by poor time responses and noise susceptibility, particularly in applications where it is a requirement that a shifting, sharp (i.e. high quality factor) mechanical resonance is tracked in real-time. Control-loop oscillators have similar drawbacks; the more sophisticated devices also require expensive, specialist digital hardware.

### SUMMARY OF THE INVENTION

Against this background, and in accordance with a first aspect of the present invention, there is provided a mechanical oscillator arrangement as set out in claim 1.

Such a stabilized positive feedback arrangement is self exciting at the effective resonance frequency of the mechanical structure and avoids the need for an external fixed or variable frequency driver. Moreover, by providing an adjustable transmission path length in the mechanical structure (for example by mounting the actuator and/or sensor for movement relative to one another), and/or by providing within the controller or another signal processing element which forms part of the oscillator control loop a means for varying an electronic frequency dependent transfer function via a frequency dependent gain element, the arrangement is capable of establishing (and desirably operates with) both stationary (standing) and travelling (propagating) mechanical vibrations. Certain preferred embodiments of this invention operating in conjunction with distributed-parameter mechanical systems, employ substantially stationary mechanical vibrations with a small propagating vibration component also present.

In these certain embodiments, employing a controllable propagating vibration component provides for improved control of the primary stationary vibrations. In particular, most distributed-parameter mechanical structures (that is mechanical structures with a characteristic dimension comparable to the wavelength of a mechanical vibration) do not have a single mechanical resonance frequency but instead, a family of vibrational modes. Embodiments of the present invention enable a particular one of these modes to be selected and locked on to provided that the sensor and actuator are correctly located and the electronic frequency dependent transfer function is appropriately designed.

In summary, the arrangements embodying the present invention permit “mode selection”, “mode-tracking” and, in certain embodiments, “mode switching” in conjunction with distributed-parameter mechanical structures. Here these three distinct functionalities are introduced along with definitions of terms which will be used in the description that follows:

“Mode selection”: The “Effective Resonance Frequency” (“ERF”) of a given implementation of the mechanical oscillator is the frequency at which the loop gain provided by the combination of the controller and the mechanical structure is unity and the total loop phase shift is substantially zero (or substantially an integer multiple of 360 degrees). Predictable, well mannered behavior of the most general form of oscillator embodying the present invention is achieved by making provision for these two conditions to be met at and only at a frequency which corresponds to a single resonant mode of the mechanical structure.

As already stated, the distributed-parameter mechanical structures relevant to certain embodiments of the invention feature not one, but a family of resonant modes. Arranging that one of these defines the ERF requires that a) the sensor and actuator components are in the correct location along the mechanical structure b) the frequency dependent gain element has an appropriate transfer function and c) that the amplitude regulator element has the particular set of characteristics that will be laid out in subsequent sections.

“Mode-tracking” is further achieved by providing a frequency dependent gain element within the oscillator controller or in an additional signal processing element which is designed in conjunction with the mechanical structure in such a way that the closed-loop arrangement is capable of supplying unity gain and substantially zero (or substantially 360n where n is an integer) loop phase shift over a certain range of frequencies which corresponds to the range over which the mode might move. In general, this range is of order the mode frequency divided by the Q of the mechanical structure (and therefore except in exceptional cases, substantially less than the “inter-mode” spacing).

In certain embodiments of the mechanical oscillator invention, “mode switching” may further be achieved by imposing a change either: a) in the electronic transfer function of the frequency dependent gain element that is present in the mechanical oscillator controller, b) in the electronic or mechanical transfer function of additional ‘signal processing elements’ that are external both to the controller and the mechanical structure, or c) the relative positions of the sensor and/or actuator components. Mode switching involves switching between an oscillator configuration which satisfies the ‘mode selection’ conditions described above at one modal frequency f1 to a frequency f2 (or f3 . . . fn) corresponding to another. In practice, this is achieved by one or a combination of the mechanisms a)-c) changing the relationship between the frequency dependent phase shift and/or gain provided by the ‘controller’ (or the controller plus additional signal processing elements) and the phase shift and attenuation inherent in the mechanical structure.

Certain embodiments of the mechanical oscillator combine the functionalities of “mode-tracking” and “mode switching”.

A non-linear amplitude control element performs the function of amplitude regulation in the oscillator feedback path, providing both a gain and a non-linearity. Either the non-linearity is provided by a particular arrangement of active components or by the inherent physical properties of a non-linear circuit component or selection of components. Desirably, the element provides at least some and preferably all of the following 4 characteristics (see later description for definition of terms and further detail):

A a small-signal dynamic gain with a large constant value which may or may not be dependent upon the polarity of the input signal;

B a small-signal quasi-linear signal regime which is approximately entirely linear;

C a strongly non-linear signal regime which features a zero large-signal dynamic gain; and

D a narrow and preferably negligibly wide transitional regime separating the quasi-linear and strongly non-linear signal regimes.

The magnitude of the non-linear amplitude control element output preferably increases monotonically with that of the input, and, in the limit of large input, the output signal has a magnitude with a negative second derivative with respect to the input signal. The characteristic might have a negative second derivative with respect to the input for all magnitudes of input signal—i.e. the output may take a certain initial value for the limit of very small input amplitude, and this value may then increase monotonically to a constant value in a non-linear fashion with increasing input. Alternatively, for values of input signal up to some limit, the gain or transconductance of the element might be constant (i.e. the second derivative of output with respect to input zero), then gradually reduce.

Further features and advantages of the present invention will be apparent from the appended claims and the following description.

### BRIEF DESCRIPTION OF THE DRAWINGS

FIGS. 1A and 1B show alternative arrangements of a mechanical oscillator device embodying the present invention, in its most general form and having a controller, an actuator, a sensor and a mechanical system;

FIG. 1C shows a cantilever exemplifying the mechanical system of FIGS. 1A and 1B;

FIGS. 1D and 1E show alternative arrangements of actuator and sensor for the cantilever of FIG. 1C;

FIGS. 2A and 2B show modified arrangements of the device of FIGS. 1A and 1B respectively;

FIG. 3 shows the controller of FIGS. 1 and 2 in further detail, including a non-linear amplitude control element (N-LACE), an amplifier and a phase compensator;

FIG. 4 shows an example of the phase compensator of FIG. 3 in more detail;

FIGS. 5A and 5B illustrate some equivalent electrical circuits for the mechanical structure of FIGS. 1A and 1B respectively;

FIG. 5C illustrates an equivalent electrical circuit for a general realization of the mechanical oscillator device of FIGS. 1A and 1B.

FIG. 6 shows an optimal idealised small and large signal input-output characteristic of the N-LACE of FIG. 3 (an “optimal Non-Linear Amplitude Control Element” (oN-LACE) characteristic);

FIG. 7A shows an idealised optimized small and large signal input-output characteristic of the N-LACE of FIG. 3 (an oN-LACE characteristic), FIGS. 7B-7D show different less optimal input-output characteristics thereof, and FIG. 7E shows the small and large signal input-output characteristics of a non-linear amplitude control element which has undesirable characteristics;

FIG. 8 shows a circuit diagram exemplifying one preferred, optimal implementation of the N-LACE of FIG. 3;

FIG. 9 shows a circuit diagram exemplifying a further preferred, optimal implementation of the N-LACE of FIG. 3;

FIG. 10 shows a circuit diagram exemplifying still another preferred, optimal implementation of the N-LACE of FIG. 3;

FIG. 11 shows a 1D mechanical system having a mechanical element suspended at each end, suitable for use in a mechanical oscillator device embodying the present invention;

FIGS. 12A-D show various modes of a membrane representing a first embodiment of a 2D flexural resonant mechanical element, clamped at two of its four edges, and suitable for use in a mechanical oscillator device embodying the present invention;

FIG. 13 shows an alternative embodiment of a 2D membrane, which is circular and clamped at its circumference, suitable for use in a mechanical oscillator device embodying the present invention;

FIG. 14 shows an example of a three dimensional flexural mechanical element suitable for use in a mechanical oscillator device embodying the present invention;

FIG. 15 shows, schematically, a first embodiment of an arrangement for the mechanical testing of jet-engine turbine or compressor blade roots, employing a mechanical oscillator device in accordance with the present invention;

FIGS. 16A-C show, schematically, parts of a second embodiment of an arrangement for the mechanical testing of jet-engine turbine or compressor blade roots, in close up, employing a mechanical oscillator device in accordance with the present invention;

FIG. 17 shows a testing apparatus formed of the components shown in FIGS. 16A-C;

FIGS. 18A-G show various embodiments of spin-wave delay-lines that may form part of mechanical structures in a mechanical oscillator device in accordance with the present invention;

FIG. 19 shows an equivalent electrical circuit of an incremental length 61 of a spin-wave delay-line;

FIG. 20 shows the electrical equivalent circuit of a spin-wave delay-line oscillator embodying the present invention, arranged in reflection mode;

FIG. 21 shows a schematic arrangement of a magnetic resonance force microscope embodying the present invention, including a cantilever suspended from a support, and having a magnetic tip that oscillates in use adjacent to a sample;

FIG. 22 shows in more detail the end of the cantilever of FIG. 21 and the sample, together with volumes of constant magnetic field strength defined by the magnetic tip;

FIG. 23 shows in more detail a first arrangement of a magnetic resonance force microscope in accordance with an embodiment of the present invention; and

FIG. 24 shows a second schematic alternative arrangement of a magnetic resonance force microscope in accordance with an embodiment of the present invention.

### DETAILED DESCRIPTION OF A PREFERRED EMBODIMENT

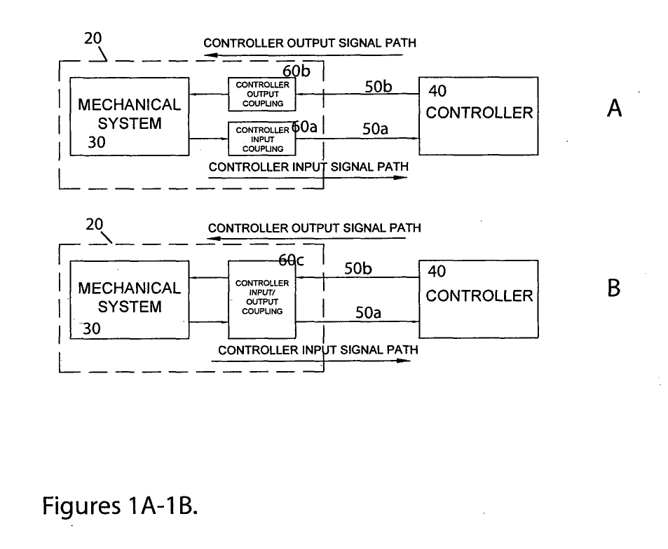

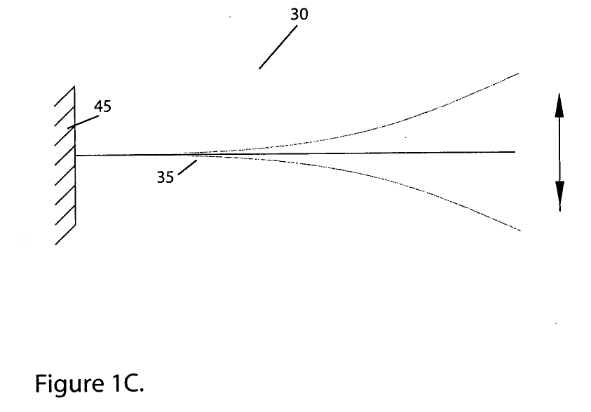

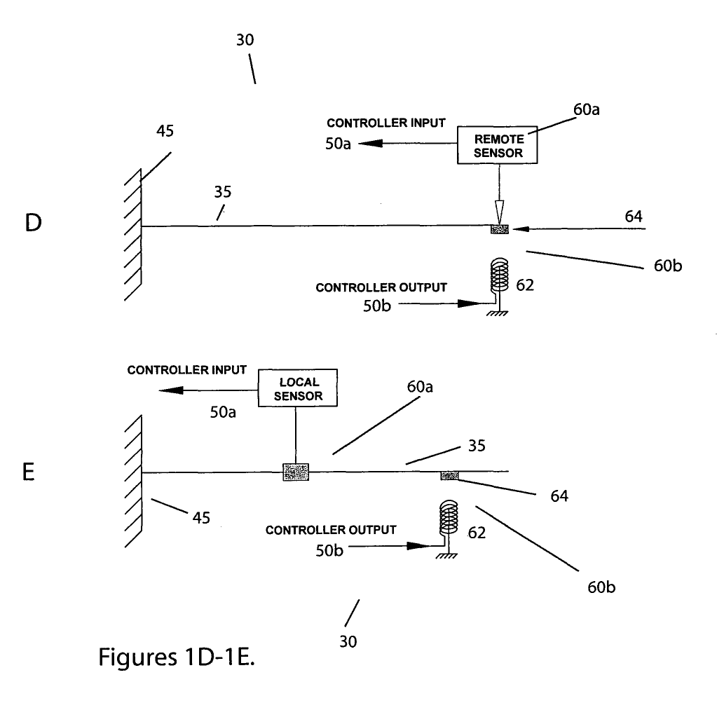

FIGS. 1A and 1B show, at a most general level, the structure of a mechanical oscillator device 10 embodying the present invention. In each case, the mechanical oscillator device comprises a mechanical structure 20 which includes a mechanical system 30, connected to a controller 40. The mechanical system 30 is the functional part or active region of the mechanical structure 20, which lends functionality to a particular implementation of the mechanical oscillator device 10. Its exact-nature depends on the desired functionality of that mechanical oscillator device, but it may be a one, two or three-dimensional mechanical element with one or more resonant mode(s), that is, a mechanical element which responds preferentially at one or more frequencies, for example, a macro, micro or nano-mechanical beam, cantilever, ring or membrane. FIG. 1C illustrates a simple schematic example of a typical mechanical system 30: a cantilever 35 which is singly clamped to a support 45 and which may be excited and controlled at a frequency corresponding to its characteristic quarter wavelength mode.

The operating frequency (ERF) of the oscillator is at least partly determined by, and generally substantially determined by, the characteristics of the resonant mechanical structure 20 which incorporates the mechanical system 30. Most preferably, the operating frequency of the oscillator substantially corresponds with the resonance frequency of the mechanical system 30 (or one of the resonance frequencies if there is more than one of these). Furthermore, the arrangements of FIGS. 1A and 1B are capable of tracking the (or one of the) resonance mode(s) of the mechanical system 30 as it shifts.

The mechanical system 30 may be ‘series-coupled’ or ‘spur-coupled’. In series-coupled implementations of the mechanical oscillator, as shown in FIG. 1A, the mechanical system 30 appears as a transmission element within the closed-loop oscillator instrumentation (see below) and the signal path within the oscillator instrumentation is accordingly at least partly mechanical. In that case, the mechanical system 30 is coupled to the controller 40 by separate controller input and output components 50a, 50b. Within the output component 50b from the controller 40 is a controller output coupling or actuator 60b. The actuator 60b provides the output coupling between the controller 40 and the mechanical system 30. The actuator 60b comprises or incorporates an actuator component or element which may for example be an inductive, charge coupled, thermal, piezoelectric or magnetostrictive actuator, or an acoustic or optical transducer. In the embodiment of FIG. 1A, the actuator is distinct from a controller input coupling or sensor 60a. The sensor 60a provides the input interface from the mechanical system 30 to the controller 40 and performs the reverse conversion to the actuator-transforming, for example, strain, velocity or position information related to the mechanical system into an electrical signal. Thus the sensor component may for example take the form of a stress or strain gauge, a piezoelectric transducer, an optical or acoustic detector or an inductive or capacitative sensor.

FIGS. 1D and 1E show a typical example of the arrangement of a series-coupled mechanical-structure 20, wherein the mechanical system 30 is the cantilever 35 which is singly clamped to the support 45 (FIG. 1C). In FIGS. 1D and 1E, a non-contact magnetic actuator 60b is employed, which incorporates a solenoid 62 connected to the controller output 50b and coupled to a permanent magnet 64 situated somewhere along the length of the cantilever 35. The motion of the cantilever 35 might be sensed via a remote sensor or detector (e.g. a laser interferometer) coupled to the controller input 50a as shown in FIG. 1D or a local sensor or detector might be employed (e.g. a strain-gauge physically connected to the cantilever), such as is depicted in FIG. 1E.

FIG. 1B shows an alternative arrangement to the series-coupled arrangement of FIG. 1A. In the spur-coupled implementation of FIG. 1B, the mechanical system 30 is coupled into the control-loop at a single point via the single, combined sensor/actuator module 60c. In such systems, the input-output transfer function of the sensor/actuator module 60c is at least partly determined by interaction with the mechanical system 30 but the signal path within the mechanical oscillator device 10 may be entirely non-mechanical.

The controller 40 provides amplification, amplitude regulation phase-compensation, and (where required) mode-selection functions such that, in combination with the mechanical structure 20, a system satisfying all the requirements of a positive-feedback controlled oscillatory system is created. More particularly, as already discussed any mechanical oscillator device system has a certain Effective Resonance Frequency (ERF). In operation, energy is supplied to the mechanical structure 20 at the ERF, and stable, constant amplitude operation of the mechanical oscillator device 10 at this frequency is maintained.

Moreover, in contrast to previous mechanical oscillator device instruments which incorporate an external fixed or variable frequency driver, the various arrangements of preferred embodiments of the present invention do not have such an external driver and instead are self-exciting at the ERF.

Furthermore, a particular feature of both series and spur-coupled implementations of the present mechanical oscillator invention is that the effective length of the transmission path within the mechanical system between actuator and sensor components is variable. This variation may be achieved either via relative motion of the actuator and sensor components, some externally imposed change in the geometry of the mechanical structure, or some externally imposed change in the geometry or characteristics of a non-mechanical system to which the mechanical structure is coupled.

In general terms, the mechanical oscillator device 10 of embodiments of the present invention operates as follows. At switch-on, the mechanical oscillator device 10 responds to the component of a weak exciting signal (for example background electrical or thermal noise) at its Effective Resonance Frequency. The response to this weak signal is received by the sensor 60a. The phase of the response signal received by the receiver component is dependent on its location along the transmission path between the actuator and sensor components and the length of the effective path. The path may be wholly or partly mechanical (“series-coupled” implementations of the mechanical oscillator invention) or entirely non-mechanical (“spur-coupled” implementations). The signal from the sensor 60a is preferentially amplified around the positive-feedback oscillator control-loop and amplitude-stable operation of the mechanical oscillator device 10 at a pre-set level rapidly established.

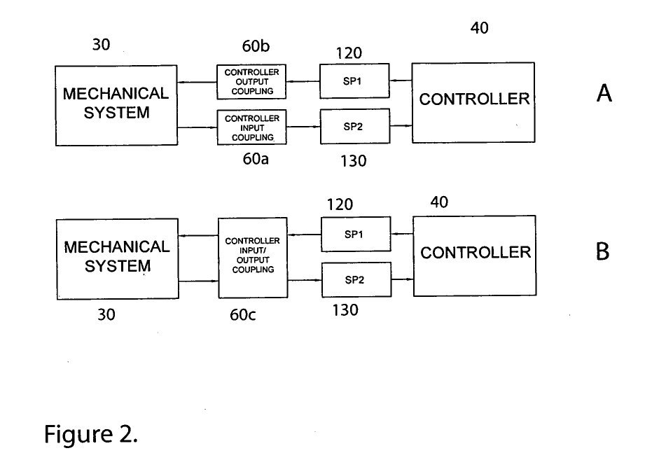

Although the most general form of the mechanical oscillator device 10 embodying the present invention is illustrated by the embodiments of FIGS. 1A and 1B, certain implementations of the mechanical oscillator device 10 may also incorporate signal processing elements 130, 120 in the input and output signal paths 50a, 50b as well. FIG. 2A shows additional signal processing elements 130, 120 included in the controller input 50a and controller output 50b paths respectively of the arrangement of FIG. 1A, whereas FIG. 2B shows an implementation in which separate signal processing elements are employed in the separate controller output and input paths 50b, 50a of the arrangement of FIG. 1B, where the actuator and sensor are combined into the single module 60c. Although FIGS. 2A and 2B show signal processing elements 130, 120 in both controller input and output paths 50a, 50b, it will be appreciated, of course, that such signal processing elements may be located in only one of the input or output paths instead.

Signal processing elements 130, 120 which might be included in either or both of the input and output signal paths 50a, 50b may operate in any physical domain (electrical, mechanical, acoustic, optical, magnetic etc) may include for example, filters, phase-compensation units and amplifiers.

The signal paths within the mechanical oscillator device may be electrical, mechanical, acoustic, optical, magnetic or any combination of these.

The means by which oscillator stabilization and control are effected in the general mechanical oscillator device 10 embodying the present invention and as outlined above, is distinct from that of prior art devices. In certain particular implementations of the mechanical oscillator device 10, the mechanical structure 20 supports a combination of a stationary (standing) vibration at a single frequency and propagating mechanical vibrations at one or more distinct frequencies. The propagating vibrational components are insignificant in magnitude in comparison with the standing vibrational component, the relative proportions of standing and propagating vibrations being controlled by the variation of the electronic transfer function of a frequency dependent gain element incorporated into the oscillator controller 40 or appearing in a separate signal processing element 120, 130 and/or, in series-coupled implementations of the invention, the effective transmission path length (as above defined).

The reception of standing and propagating vibrations by the sensor 60b is important to the correct functioning of certain particular implementations of the device 10 which accords with the present invention.

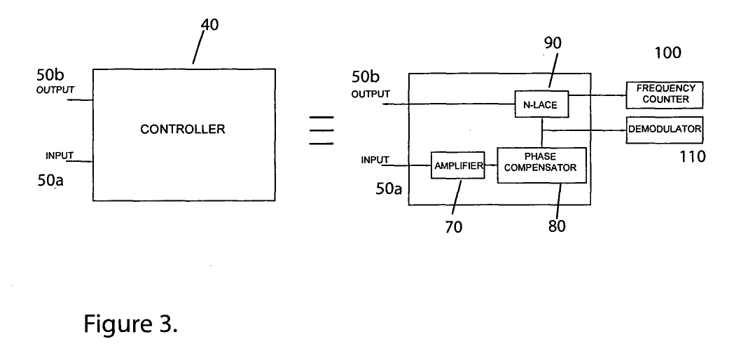

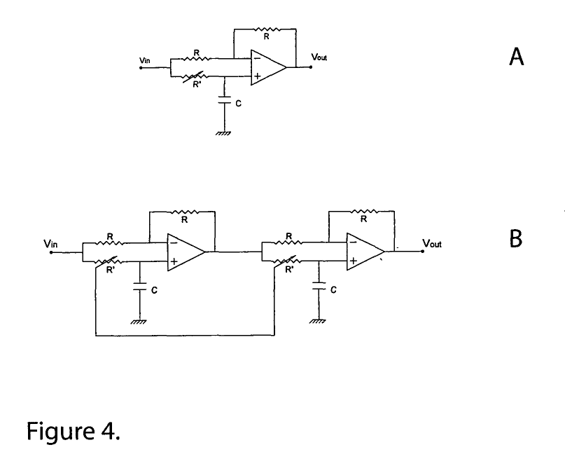

FIG. 3 shows a block diagram of the mechanical oscillator device controller 40 of FIGS. 1A, 1B, 2A and 2B in more detail. The controller 40 incorporates an amplifier 70 such as, for example, a non-inverting pre-amplifier realized in discrete or surface mount electronic components and incorporating a low noise, high input impedance operational amplifier. The controller also includes a phase compensator 80 which typically follows the amplifier. Many possible realizations of a phase compensator component are possible in the context of the mechanical oscillator device 10, although in general the phase compensator operates in the analogue, electrical domain. One possible example of a phase compensator circuit is shown in FIG. 4B. It comprises two units (FIG. 4A) in series. Each unit has transfer function:

$$P ( j ω ) = \frac{{V}_{out} ( j ω )}{{V}_{i n} ( j ω )} = \frac{1 - j ω {CR}^{′}}{1 + j ω {CR}^{′}} . \qquad ( 1 )$$

The gain is unity at all frequencies, whilst the phase is given by

LP(jω)=−2 arctan(ωCR′) (2)

Thus, by cascading two such circuits and incorporating a ganged potentiometer, (for approximately constant ωC) the relative phase of the output and input may be varied between 0 degrees (R′=0) and 360 degrees (ωCR′>>1).

The final component of the controller 40 is an amplitude regulator which, in the preferred embodiment of the present invention, is a non-linear amplitude controller (N-LACE) 90, and further, in the most preferred embodiment of the present invention is an optimal non-linear amplitude control element (oN-LACE, see detail later). This N-LACE 90 is particularly preferred as a means for providing oscillator stabilization. The amplifier, phase compensator and N-LACE are the minimum elements required in the controller 40, for the functioning of the mechanical oscillator device 10, though other electronic components may also be incorporated into the controller 40. An example of an additional electronic element which might be incorporated into the controller 40 is a component which provides a fixed or variable frequency dependent electronic transfer function.

The characteristics of the N-LACE 90, together with some examples of circuits providing these characteristics, are set out in further detail below. In general terms, however, it may be noted that the non-linear characteristics of the N-LACE 90 might be obtained using a variety of instrumentation techniques: the element may comprise or incorporate an active device with a negative differential conductance by virtue of a physical positive-feedback process. Alternatively, the desired non-linear characteristic may be achieved via a positive-feedback amplifier configuration.

At least one amplifier component (shown in FIG. 3 as a single block 70) appears at the input 50a to the controller 40 from the mechanical structure 20. Additional (optional) amplifier components may also be included in the controller 40. For example, an additional amplifier component (not shown) may appear at the output 50b of the controller 40.

Outputs related to the frequency and level (amplitude) of the oscillator's operation may be extracted; this is indicated in FIG. 3 by the presence of the frequency counter 100 and demodulator 110.

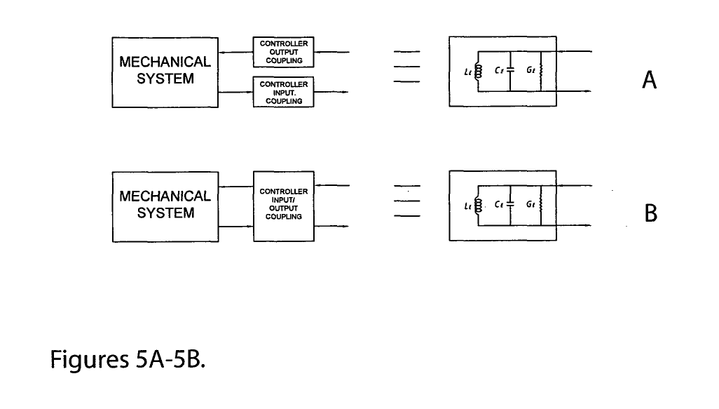

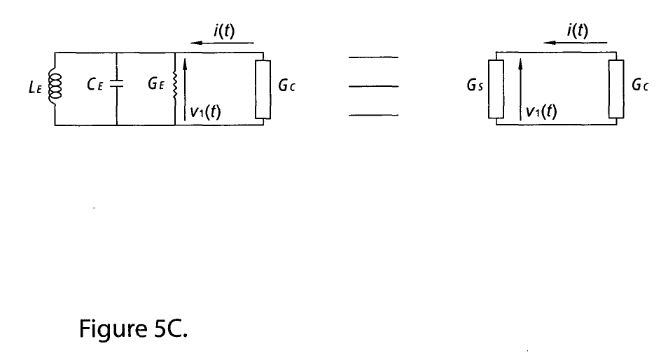

In accordance with preferred embodiments of the present invention, the oscillator instrumentation that drives the mechanical structure 20 is constituted in its most general sense of an active electronic amplifier, together with a phase compensator, a frequency dependent gain element with an electronic transfer function and amplitude regulator configured to provide a conditionally stable positive feedback loop. Appendix A derives the characteristics of the N-LACE 90 by treating the mechanical oscillator device 10 in terms of an entirely electrical equivalent two terminal electrical circuit, as depicted in FIGS. 5A, 5B and 5C, the mechanical structure 20 being represented by three shunt elements: an effective inductance L_{E}, a capacitance C_{E}, and a conductance G_{E}, together having a combined impedance G_{S}. In this representation, the instrument controller 40 incorporating the non-linear amplitude control element (N-LACE) 90 may be modelled by a shunt conductance G_{c} as depicted in FIG. 5C, and the operation of the mechanical oscillator device 10 may be described in terms of two time-dependent oscillator control signals: an equivalent current ‘output signal’ i(t) which flows into the combined impedance G_{S}), and originates from G_{c}, and an equivalent voltage ‘input signal’ ν₁(t) which appears across G_{S}. In general, G_{c} will be a complex, frequency dependent conductance with a negative real part and non-linear dependence on ν₁(t).

The function of the N-LACE 90 is to provide an amplitude regulated feedback signal i(t) to drive the mechanical structure 20. In general terms, the N-LACE provides gain and non-linearity. There are several ways in which this can be achieved, although as will be seen, some of these are more preferred than others since they provide for optimized performance of the mechanical oscillator device 10.

From henceforth, for ease of reference and to distinguish the preferred embodiment of a non-linear amplitude control element (with particularly desirable characteristics to be detailed below) from the more generalised (arbitrary) non-linear amplitude control element 90, the acronym “oN-LACE” (optimised non-linear amplitude control element) will be employed.

To summarise the properties of the optimal non-linear amplitude control element that is preferably employed in the mechanical oscillator device of embodiments of the present invention, it features three distinct signal regimes: a small-signal or quasi-linear regime (SS), a transitional signal regime (T) and a large-signal strongly non-linear regime (LS). In assessing the performance of a general non-linear amplitude control element there are four key parameters to consider:

1. The small-signal dynamic gain g_{dSS} at time t₁:

$${{g}_{dSS} ( {t}_{1} ) = \frac{\partial i ( {t}_{1} + τ )}{\partial v ( {t}_{1} )} \vert}_{SS}$$

where τ is a time delay characteristic of the input-out conversion in the N-LACE 90, which may or may not be frequency dependent.

2. The linearity of the small-signal quasi-linear regime.

3. The width of the transitional regime (T)—i.e. the range of input signal amplitudes for which the N-LACE response would be described as transitional.

4. The large-signal dynamic gain g_{dLS} at time t₁:

$${{g}_{dLS} ( {t}_{1} ) = \frac{\partial i ( {t}_{1} + τ )}{\partial v ( {t}_{1} )} \vert}_{LS}$$

where r is as previously defined.

In the most preferred embodiment of the oN-LACE described in the context of the mechanical oscillator device, the small-signal dynamic gain (1) takes a large constant value which may or may not be dependent on the polarity of the input signal; the small-signal quasi-linear signal regime is approximately entirely linear (2), the transitional regime (T) (3) is so narrow as to be negligible, and the large-signal (LS) dynamic gain is zero.

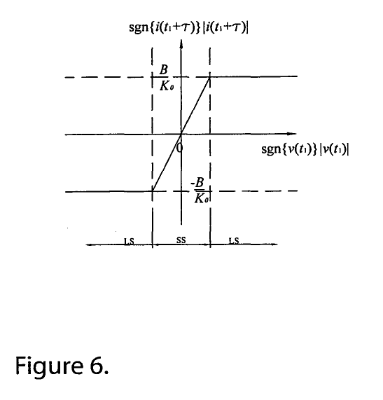

FIG. 6 illustrates such an oN-LACE input-output characteristic for which the small-signal dynamic gain is K₀, independent of the polarity of the input signal ν(t) and the positive and negative amplitude thresholds have equal magnitude B. However, non-linear amplitude control elements with characteristics other than those shown in FIG. 6 are also contemplated.

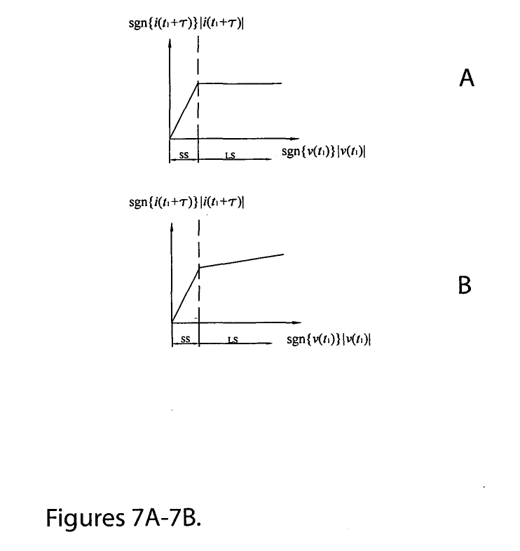

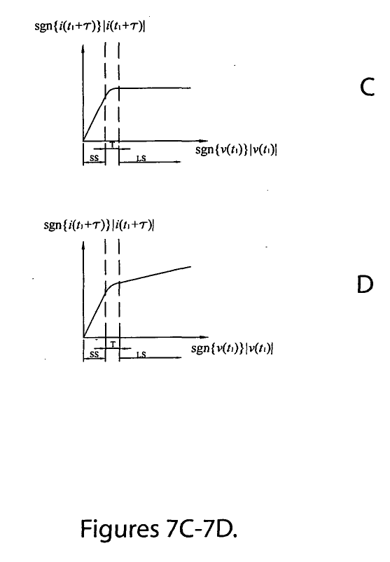

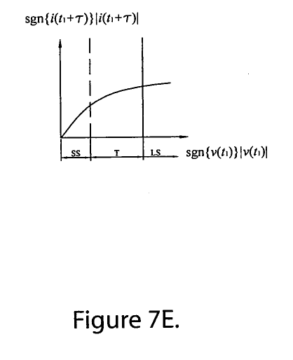

The family of non-linear amplitude control element input-output characteristics that fall within the oN-LACE definition are illustrated in FIGS. 7A-7D. FIGS. 7A-7D show only the oN-LACE input-output characteristic for positive values of instantaneous input signal ν(t₁). Note that the relative polarities of the oN-LACE input and output signals are arbitrarily defined. In general, the input-output characteristics may be symmetric in ν(t₁), anti-symmetric in or entirely asymmetric in ν(t₁). FIG. 7A shows the ‘ideal’ input-output characteristic—this is entirely equivalent to the section of the graph of FIG. 6 for positive ν(t₁) the small-signal quasi-linear signal regime (SS) is approximately entirely linear, the transitional regime (T) is so narrow as to be negligible, and the large-signal (LS) dynamic gain is zero. FIG. 7B shows an oN-LACE input-output characteristic, less favourable than the ideal characteristic of FIG. 7A though still representing an advantageous arrangement of oN-LACE suitable for use in the context of a mechanical oscillator device embodying the present invention. Here, the small-signal quasi-linear signal regime (SS) is—as in the ideal case—approximately entirely linear, and the transitional regime (T) is so narrow as to be negligible. However, there is a non-zero large-signal dynamic gain. Although non-zero, this large-signal dynamic gain is very much smaller than the small-signal dynamic gain i.e. g_{dSS}>>g_{dLS}.

FIG. 7C shows another oN-LACE input-output characteristic, which is likewise less favourable than the ideal characteristic of FIG. 7A but nonetheless still advantageous in the context of a mechanical oscillator device embodying the present invention. Here, the small-signal quasi-linear signal regime (SS) is—as in the ideal case—approximately entirely linear and the large-signal dynamic gain is approximately zero. However, there is a transitional regime (T) of finite width separating the small-signal quasi-linear (SS) and large-signal (LS) regimes. In this transitional region, the behaviour of the oN-LACE is neither quasi-linear nor strongly non-linear.

FIG. 7D shows yet another oN-LACE input-output characteristic, which is likewise less favourable than the ideal characteristic of FIG. 7A but nonetheless still advantageous in the context of a mechanical oscillator device embodying the present invention. Here, the small-signal quasi-linear signal regime (SS) is—as in the ideal case—approximately entirely linear. However, there is a transitional regime (T) of finite width separating the small-signal quasi-linear (SS) and large-signal (LS) regimes. In this transitional region, the behaviour of the oN-LACE is neither quasi-linear nor strongly non-linear. Additionally, there is a non-zero large-signal dynamic gain. Although non-zero, this large-signal dynamic gain is very much smaller than the small-signal dynamic gain i.e. g_{dSS}>>g_{dLS}.

Other oN-LACE input-output characteristics are possible that are less favourable than the ideal characteristic of FIG. 7A but still provide advantages in the context of a mechanical oscillator device embodying the present invention. For example, a slight non-linearity in the small-signal quasi-linear signal regime may be tolerated, as might a slight non-linearity in the large-signal regime. Combinations of slight non-idealities not explicitly described here are also permissible, for example: in a given oN-LACE characteristic there may be observed a slight non-linearity in the small-signal quasi-linear regime (SS), a narrow but non-negligible transitional region (T) and a small but non-zero large-signal dynamic gain g_{dLS} etc.

FIG. 7E shows a non-optimised N-LACE input-output characteristic which would not be preferred. Here, the small-signal (SS) regime differs considerably from the ideal, linear characteristic, the transitional regime (T) is wide such that one could not describe the transition from small-signal (SS) to large-signal (LS) regimes as ‘abrupt’ but might rather refer to it as ‘gradual’. The large-signal dynamic gain is also non-zero and the large-signal input-output response has some non-linearity. Such a non-optimised N-LACE characteristic would not support optimally rapid oscillator stabilization, frequency tracking (see description of “mode-tracking” applications later) or optimal immunity to noise/disturbance.

In the most general sense, there are two different ways in which non-linear amplitude control functionality may be achieved. The first type of non-linear amplitude control incorporates a discrete active circuit element or an arrangement of discrete active circuit elements which provides a negative differential conductance or transconductance (i.e., gain) and a non-linearity. The non-linearity, and, in the majority of cases part or all of the gain, are each provided by a physical, non-linear process which is an inherent property of one or more of the circuit elements.

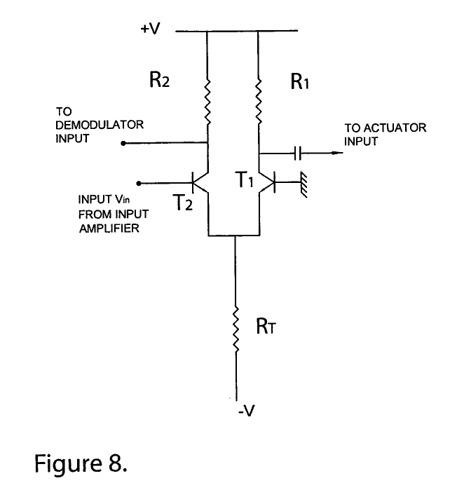

The functionality of the second type of non-linear amplitude controller is entirely equivalent to that of the first, but here, the non-linearity is provided not by an inherent physical non-linear process, but by deliberately arranging active elements so that the desired non-linear behaviour is promoted. One way of doing this is, for example, to exploit the gain saturation of an operational amplifier, or to use a transistor pair, as exemplified in FIGS. 8, 9 and 10 (see below).

In both types of non-linear amplitude controller, the provision of gain and the provision of non-linearity may be considered as two independent functional requirements, which might accordingly be provided by two distinct functional blocks. In practice, the gain-non-linearity combination is often most readily achieved by exploiting the properties of a single collection of components. In any event, at least conceptually, the non-linearity may be considered as being superimposed on top of a linear gain characteristic, to create the desired set of input-output characteristics.

Considered in this way, the key function of the non-linearity is then to limit the maximum value of the gain (or the transconductance, or simply the output signal) of the overall amplitude regulator circuits. Overall, the intention is that the combination of the “gain” functionality and the “non-linear” functionality provides a unit which delivers a significant gain for small signals, that has a constant magnitude output once the input exceeds a pre-determined threshold, as explained above.

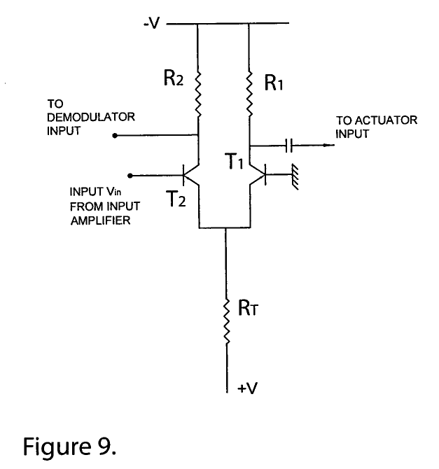

FIGS. 8 and 9 show two simple exemplary circuits suitable for providing the desirable characteristics of an oN-LACE as outlined above. Each circuit is of the second type of non-linear amplitude control described above, that is, each provides a circuit induced non-linearity provided by a pair of bipolar junction transistors. In the case of the arrangement of FIG. 8 the bipolar junction transistors are NPN, whereas in the case of FIG. 9 PNP transistors are employed.

Looking first at FIG. 8 a first embodiment of an oN-LACE is shown. The arrangement of FIG. 8 employs first and second NPN transistors T₁ and T₂, arranged as a long-tailed pair differential amplifier. The amplifier 70 (FIG. 3) provides an input voltage Vᵢₙ to the base of transistor T₂. The base of transistor T₁ is grounded. The collector of transistor T₁ is connected to a positive voltage rail +V via a first resistor R₁, and a collector of the second transistor T₂ is connected to the same positive voltage rail via a second resistor R₂. The emitters of each transistor T₁, T₂ are connected in common to a negative voltage rail −V via a tail resistor R_{T}.

The collector of the first transistor T₁ is capacitively coupled to the actuator 60b. Thus the circuit of FIG. 8 provides an amplified and current regulated version of the circuit input to the base of transistor T₂ to drive the actuator 60b. In addition, this regulated output from the collector of the first transistor T₁ may be connected to the frequency counter 100 (FIG. 3) to provide a frequency output.

The collector of the second transistor T₂ provides a second circuit output to the demodulator 110 (see FIG. 3 again). This output from the collector of the second transistor T₂ is an AC signal at the frequency of the input signal Vᵢₙ with an amplitude proportional to that input voltage. This input level dependent signal, when demodulated by the demodulator 110, recovers a DC signal which is proportional to the input level. This DC signal may for example be employed to monitor changes in the quality factor (Q) of a resonance of a mechanical system. More specific details of this use of the demodulator output are set out below, where some examples of particular implementations of the mechanical oscillator device 10 embodying the present invention are described.

FIG. 9 shows an alternative circuit arrangement to that of FIG. 8. The configuration is identical save that the transistors T₁ and T₂ are, in FIG. 9, PNP transistors, and the voltage rails are thus reversed.

In each case of the circuit arrangements of FIGS. 8 and 9, for small amplitudes of input, injecting a signal at the base of the second transistor T₂ results in a proportional current flow in the collector of the first transistor T₁ (and hence to the actuator via the capacitative coupling)—this is the linear regime of the oN-LACE and is provided via the small-signal “linear gain” regime of the transistor pair. Once the input reaches a certain threshold value, the first transistor T₁ is instantaneously driven “fully on”, and its collector current accordingly saturates at a predetermined value. This provides the “strongly non-linear” characteristic of the oN-LACE.

In each of the circuits of FIGS. 8 and 9, the collector current of the second transistor T₂ varies with the voltage amplitude of the input signal for all values of input. Demodulation of this signal by the demodulator 110 provides, therefore, a means to monitor the amplitude of the input to the circuit, and, accordingly when the oscillator is operating in steady state, so that the actuator is driven at constant current, the loss characteristics of the mechanical system can likewise be monitored.

The convenient “dual” action of the circuits of FIGS. 8 and 9 (that is, the provision of an input-proportional current in the collector of the second transistor T₂, and a current with a non-linear dependence on input signal in the collector of the first transistor T₁) is by virtue of the broken symmetry of the common-emitter pair, i.e., the fact that the signal is supplied to the base of the second transistor T₂, whilst the base of the first transistor T₁ is grounded (earthed).

The abrupt transition between the linear and strongly non-linear regions, and the stability of the strongly non-linear region, are each achieved by a combination of:
(i) the speed and repeatability of response of the transistor pair T₁, T₂; and
(ii) the abrupt, non hysteretic transition between linear amplifying and “fully on” regimes for the two transistors; as well as
(iii) the pronounced asymmetry of the circuit.

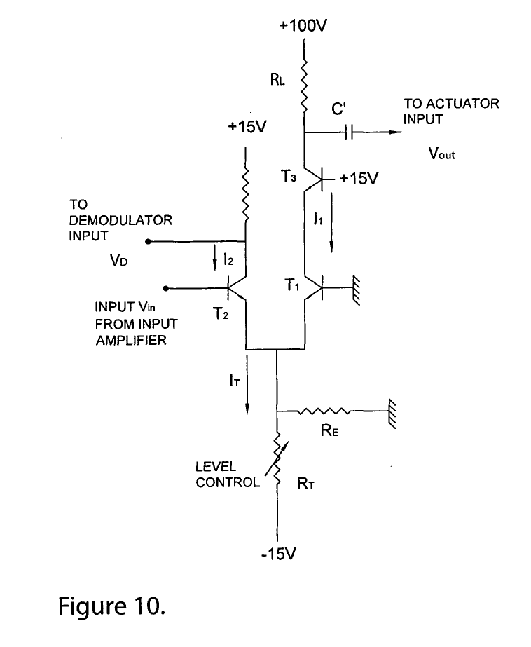

Regarding (i) and (ii), for oN-LACE functionality, it is desirable that the phase shift associated with the signal conversion process of the oN-LACE is small and most preferably negligible. For a general non-linear amplitude control element to function correctly, it is necessary that the electronic blocks which provide the required gain and non-linearity device deliver a phase shift which is less than and preferably much less than 45 degrees. Optimally (that is, in the case of the preferred oN-LACE non-linear amplitude control element), only a very small phase shift is tolerated, say, less than about 2 degrees. Such “fast conversion” functionality is delivered by the embodiments of FIGS. 8 and 9, as well as the embodiment of FIG. 10 which will now be described.

FIG. 10 shows a combined, regulator detector circuit which also is capable of providing optimised non-linear amplitude control. The circuit of FIG. 10 incorporates a high voltage rail (in the embodiment of FIG. 10, a positive voltage rail of 100 volts is employed) together with level detection functions in conjunction with an actuator which may for example take the form of a solenoid or piezoceramic transducer. As with the arrangements of FIGS. 8 and 9, the input to the circuit is Vᵢₙ supplied from the amplifier 70 (FIG. 3) to the base of a second transistor T₂ of NPN type. The base of the first transistor T₁ is grounded.

As with the arrangements of FIGS. 8 and 9, the transistors T₁ and T₂ constitute a differential amplifier configured as a long-tailed pair. Rather than a single, fixed resistive load connecting the emitters of the transistors to the negative voltage rail, however, the tail of the differential amplifier is formed of a resistive network comprising an emitter resistor R_{E} in combination with a variable tail resistor R_{T}. This combination of resistors, one of which is variable, acts as level control by adjusting the tail current I_{T}. The resistor R_{E} may be adjusted manually so as to set the maximum amplitude of the signal driving the actuator, or in more sophisticated arrangements, may be automatically adjusted by a subsidiary control loop. This automatic adjustment may for example be in response to a secondary feedback signal (for example a signal related to the progress of a process being carried out in the mechanical structure or another system (mechanical or otherwise) coupled thereto).

Unlike the arrangements of FIGS. 8 and 9, however, the arrangement of FIG. 10 employs an active load which in the illustrated embodiment is a third NPN transistor T₃. This is connected so that the emitter of transistor T₃ is connected to the collector of the first transistor T₁. The base of the third transistor T₃ is connected to the positive voltage rail (+15 volts in the example of FIG. 10). The collector of the third transistor T₃ is connected, via a load resistor R_{L} to high voltage source feed, which is, as illustrated, for example 100 volts.

The circuit of FIG. 10 contains two outputs: a first from the collector of the second transistor T₂ is a voltage V_{D} which is an AC signal at the frequency of the input signal Vᵢₙ with an amplitude dependent upon that signal. This voltage V_{D} may be supplied to the demodulator 110 of FIG. 3 so as to recover a DC signal proportional to the input level. This DC signal might for example be used to monitor changes in the quality factor (Q) of a resonance of a mechanical structure.

The second circuit output is labelled Vₒᵤₜ and is capacitively coupled from the collector of the third transistor acting as an active load to the differential amplifier of FIG. 10. Vₒᵤₜ is an amplified and current regulated version of the circuit input Vᵢₙ. Vₒᵤₜ drives the actuator 60b. This output signal Vₒᵤₜ may also be connected to the frequency counter 100 of FIG. 3, to provide a frequency output. Unlike the simple arrangement of FIGS. 8 and 9, the circuit of FIG. 10 allows direct high-current drive to the actuator.

Mechanical oscillator devices embodying the present invention may conveniently be divided into two broad categories. A first category of devices includes those in which the mechanical structure 20 incorporates a lumped mechanically resonant element, and in particular a one, two or three dimensional lumped mechanically resonant element. Such devices may be useful across a range of applications such as (but not limited to) materials or component testing, for example the fatigue testing of components for aerospace, industrial or power generation applications, the control of micro or nano scale mechanical systems (so-called NEMS or MEMS systems), and information processing applications.

The second (broader) category of devices includes those in which the mechanical structure incorporates a distributed-parameter resonant mechanical element which may provide a phase shift between the actuator and the sensor that varies continuously with frequency. The frequency response of such an element is characterised by a fundamental resonant mode and, in theory, an infinite series of harmonic modes. In a practical mechanical oscillator device realized in conjunction with such a distributed-parameter resonant mechanical element, the number of accessible or significant modes is limited by the real physical properties of the mechanical element and the operating bandwidth of the sensors and actuators which constitute or form part of the controller input and output coupling components.

Devices including a lumped mechanically resonant element have a single resonant mode at a frequency ω₀. This single resonant mode may however shift in time as a result of changes in the effective mass and/or stiffness of the lumped mechanical element, and embodiments of the present invention permit that mode to be tracked in accordance with the principles outlined below. Alternative embodiments of the present invention deliver mode selection, mode-tracking and optionally mode switching functionality in conjunction with distributed-parameter mechanical elements in accordance with the definitions already laid out and previous and subsequent discussion.

In both categories of device, changes in the loss characteristics of the mechanical element may also be monitored via the effect of these changes on the Q of the mechanical structure of the mechanical oscillator device.

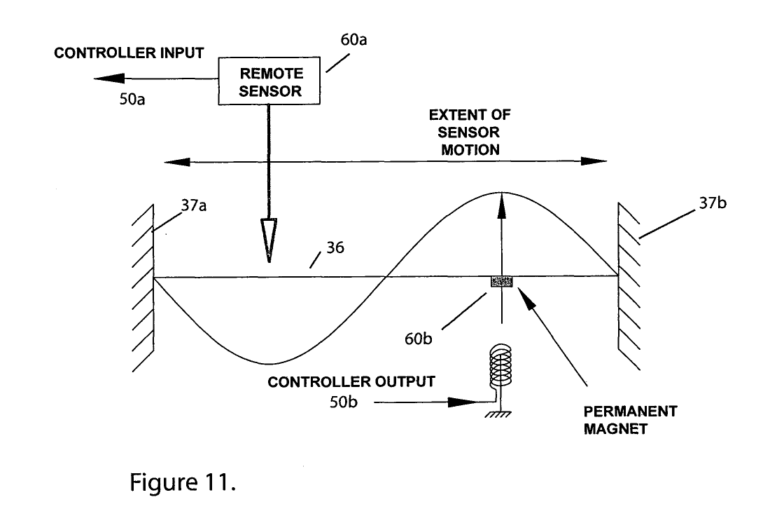

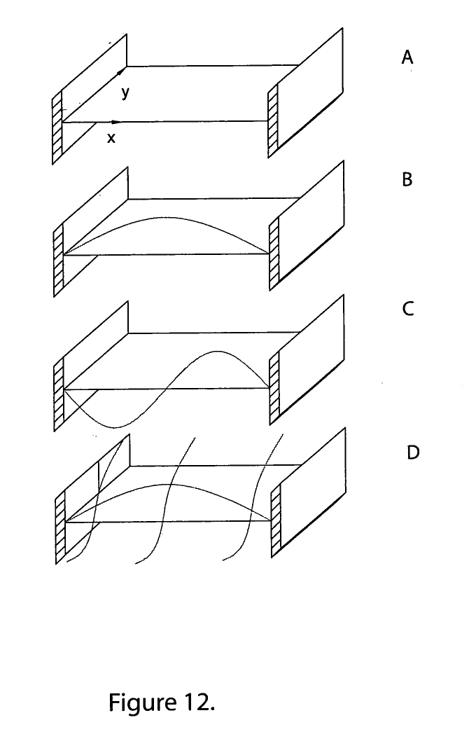

Some detailed examples/applications of devices including both lumped and distributed-parameter resonant elements are shown in FIGS. 11 to 24 and are described below.

Mode-Tracking

Certain intended implementations of the mechanical oscillator devices embodying the present invention involve “mode-tracking”. The Effective Resonance Frequency (ERF) of the mechanical oscillator is a frequency which corresponds substantially to a resonant mode of the mechanical structure and, through the action of the controller 40, the frequency corresponding to this resonant mode remains the ERF of the oscillator, even if this frequency varies. In such mode-tracking implementations, a resonant mode of the mechanical structure 20, the frequency of which varies in time, defines the ERF of the oscillator and this mode is stabilized via a feedback signal generated from a raw sensor output which further in certain particular implementations is itself derived from a superposition of stationary and propagating vibrations at the sensor's location in the mechanical system. In such mode-tracking implementations, the oscillator controller 40 responds to discrete or continuous changes in the frequency corresponding to the resonant mode, (such as might be brought about by physical changes in the mechanical structure), bringing about a corresponding and approximately instantaneous discrete or continuous compensating variation in the operating frequency of the oscillator. For optimal mode-tracking performance, it is desirable that the amplitude control element within the oscillator controller is of the optimal type whose characteristics are described above and illustrated by example in FIGS. 8-10, so that the changes in the mechanical structure can be tracked rapidly and accurately by changes in the oscillator operating frequency.

Such implementations find use in a wide range of instrumentation and measurement applications where it is useful or desirable to effect the resonant or substantially resonant excitation of a mechanical element for measurement or automation purposes. Moreover mode-tracking implementations of the mechanical oscillator are particularly suitable for measurement applications, where it is useful or desirable to measure a phenomenon or quantity via its effect (which may be discrete or continuous in time) on a particular resonant mode of a mechanical system: specifically its effect on the frequency and quality factor Q of the mode.

The oN-LACE introduced above offers superior performance over a general non-linear amplitude control element in mode-tracking: mechanical mode-tracking applications require that the ERF of the mechanical oscillator device 10 is a frequency corresponding to a resonant mode of the mechanical structure equivalent electrical system i.e.

$${ω}_{0} = \frac{1}{\sqrt{{L}_{E} {C}_{E}}} . \qquad ( 3 )$$

where, with reference to FIGS. 5A-C L_{E} and C_{E} are the mechanical structure equivalent circuit inductance and capacitance, respectively.

Note that in mode-tracking implementations of the mechanical oscillator device, it is not necessarily the case that the mechanical structure has a single resonance frequency. In certain applications, the mechanical structure 20 may have a significant multiplicity of resonant modes, one of which it is desirable to select as the operating frequency of the mechanical oscillator device 10.

Appendix A derives the conditions for mode-tracking functionality in the general case of a mechanical oscillator device 10 with a non-linear amplitude controller, in terms of an equivalent circuit. In a general mechanical oscillator device 10 such as is illustrated in FIGS. 1A, 1B, 2A and 2B, incorporating a general N-LACE 90, small changes or fluctuations in the values of the coefficients g₀ and g₂, representing coefficients in a polynomial expansion of an amplitude regulator equivalent negative conductance (see Appendix A for further details), may have a profound effect on the amplitude of oscillation. As a result, such arrangements may be temperamental, and a subsidiary slow-acting amplitude control-loop may be required to promote reliable operation. This subsidiary control-loop is undesirable for several reasons—it adds complexity, it can lead to ground bounce (“motorboating” or “squegging”) and parasitic oscillation of the mechanical oscillator device 10 and it fundamentally limits the speed of the control-loop response to changing mechanical structure parameters.

In the case that the N-LACE 90 is of the preferred, optimal type oN-LACE described previously (in which there is as sharp as possible a transition between the quasi-linear (small-signal) and strongly non-linear (large-signal) regimes), in the steady-state oscillator regime the oN-LACE output has a particular power spectral density and an amplitude that takes a value that is generally approximately independent and preferably entirely independent of the instantaneous value of the input.

The steady-state output is independent of the actual negative conductance presented by the non-linearity and thus the parameters of the real devices that make up the oN-LACE. Predictable, robust performance is thus promoted without the need for any subsidiary slow-acting control-loop.

Mode Switching

The mechanical oscillator devices described herein typically feature not one, but a number of possible operating frequencies or operating ‘modes’. Thus, modal selectivity—the ability to select a single operating mode which is favoured over all others—is desirable. In certain implementations of the mechanical oscillator device it is desirable to operate the oscillator at a frequency which corresponds to a single, known operating mode of the system. Additionally, the ability to switch between possible operating modes—i.e. to select different operating modes of the device according to the application—may be beneficial. Mode ‘switching’ functionality is a particular advantageous feature of certain implementations of the mechanical oscillator device embodying the present invention.

In the context of the mechanical oscillator device it is desirable to excite a single oscillator mode—i.e. to suppress mechanical vibrations at all but one of the frequencies at which the mechanical structure responds resonantly.

In the context of the ‘mode switchable’ mechanical oscillator devices described above, selection and stabilization of multiple modes is made possible by the fact that the effective transmission path length within the device is variable (see earlier description) and that in any implementation of the mechanical oscillator, a frequency dependent gain element having an electronic transfer function is present in the oscillator control loop and that in certain particular implementations of the mechanical oscillator device, both propagating and stationary mechanical vibrations are sensed by the sensor component. In a given general implementation of the mechanical oscillator device invention, one or more of three mode selection techniques may be employed.

The first technique for mode selection and stabilization employs frequency dependent gain. This technique involves the use of an appropriately designed frequency dependent gain element in the oscillator controller 40 or in an additional signal processing element. In general, though not necessarily, such a frequency dependent gain operates in the electrical analogue domain and may for example, take the form of a low-pass, high-pass, bandpass or notch filter.

A second technique for mode selection and stabilization employs hardware design, implementation and arrangement. The technique involves designing the mechanical structure 20 particular to a mechanical oscillator device 10 such that one or more desired operable modes are extant whilst others are precluded. The mechanism by which unwanted modes are precluded or accessed is either or a combination of actuator or sensor design, placement or motion.

A third method of mode selection and stabilization uses frequency dependent phase shift. This method is enabled by the fact that, in a distributed-parameter mechanical structure, the phase information returned to the mechanical oscillator device controller 40 by the sensor 60a is dependent upon both its position relative to the mechanical structure 20 and its frequency of operation. Thus a combination of the positioning (or variable positioning) of the sensor 60a, and variable phase input from a phase compensator component 80 may be used to select and stabilize a desired operating mode. An example is illustrated in FIG. 11, which shows a 1D mechanical system having a mechanical element 36 suspended at each end from supports 37a and 37b. The controller output 50b is connected to a solenoid which when energised actuates a permanent magnet mounted upon the mechanical element 36. This in turn causes oscillatory movement of the mechanical element 36 in a sinusoidal manner as shown in FIG. 11. A remote sensor 60a detects movement of the mechanical element 36 and outputs a signal to the controller input 50a. The remote sensor is moveable in the direction of elongation of the mechanical element 36, that is, between the two supports 37a, 37b. Any oscillator mode may be enabled using this technique so long as the conditions for observability and controllability of this mode are satisfied.

Multiple Actuators/Sensors

The foregoing has considered devices having a single fixed actuator and fixed sensor (either combined or separate). However, devices incorporating distributed-parameter mechanically resonant elements or systems may include one or more of the following as well or instead:

1. A single fixed actuator in combination with multiple fixed sensors.

2. A single fixed sensor in combination with multiple fixed actuators.

3. Multiple fixed actuators and sensors.

4. A single moveable or moving sensor and fixed actuator.

5. A single fixed actuator and moveable or moving sensor.

In 1 and 2 above, the mechanical mode selected depends on which sensor (when there are multiple sensors) and/or which actuator (when there are multiple actuators) is included in the oscillator control loop and the phase shift (or equivalently the time delay) provided by the remainder of the controller components. In order to switch between operable modes without modifying the phase shift provided by the remainder of the control-loop components, M sensors (when there are multiple sensors) and/or M actuators (when there are multiple actuators) are required and these must be positioned at ‘equivalent phase’ positions along the mechanical element. The concept of equivalent phase positions is most easily understood by example: two sensor positions P1 and P2 are equivalent phase if, when the mechanical element is excited at two corresponding frequencies f₁ and f₂, the phase shifts between system input (i.e. the actuator) and the sensors at P1 and P2 are equal or equivalent (i.e. spaced by 360n degrees where n is any real integer including zero). Switching between modes may be performed by electrically switching between sensors (when there are multiple sensors) and/or actuators (when there are multiple actuators). In a mechanical oscillator device where it is desirable to control more than one resonant mode of a given mechanical structure independently of another, separate controllers 40 are required, each operating at the mode frequency of the respective mode to which it is locked.

Mode selection as outlined above may be exploited to realize mode-tracking implementations of the mechanical oscillator device with the capacity to operate at frequencies co-incident with two or more resonant modes of a multi-modal distributed-parameter mechanical system. Simultaneous independent control of two or more resonant modes of such a multi-modal distributed-parameter mechanical system requires separate mechanical oscillator device controllers for each mode.

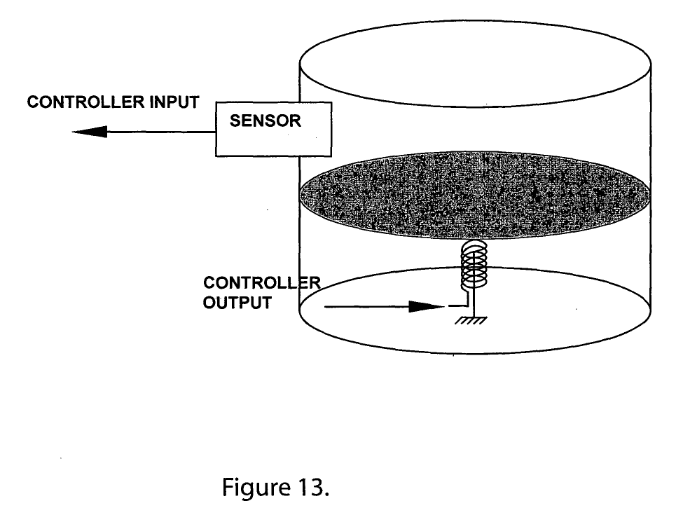

The mechanical oscillator devices described may be realized in conjunction with a wide range of distributed-parameter mechanical system geometries. As well as one dimensional distributed-parameter mechanically resonant elements, mechanical oscillator devices in accordance with embodiments of the present invention may be implemented in conjunction with 2D mechanically resonant elements. An example of a 2D flexural resonant mechanical element is a membrane, clamped at two of its four edges (FIG. 12). The family of resonant modes of such a 2D system may be decomposed into two orthogonal directions (x and y in FIG. 12). The boundary conditions for x and y may be equivalent or distinct. FIG. 12 indicates the latter case—both limits of the flexural plane are clamped in the x-direction whilst both limits are clamped in the y-direction. The eigenmodes of the element are combinations of x and y modes. FIG. 13 is a further example of a 2D mechanical flexural element suitable for use as a mechanical system 30 of a mechanical oscillator device 10. The circular membrane is excited by the actuator at its centre. The modes of such a circularly symmetric element are Bessel functions. Higher order modes may be excited by varying the radial position of the actuator or by incorporating multiple actuators.

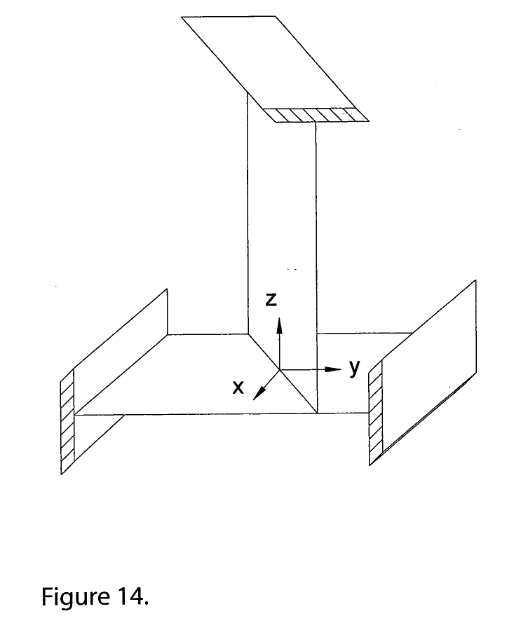

FIG. 14 shows an example of a three dimensional flexural mechanical element which may constitute a (or part of a) mechanical system 30 in accordance with another embodiment of the present invention. The family of resonant modes of such a 3D element may be decomposed into three orthogonal directions (for example x, y and z in FIG. 14). The eigenmodes of the element are the complete set of combinations of x, y and z modes.

Having provided an overview of the features and functions of mechanical oscillator devices embodying the present invention, a range of specific applications will now be set out, based upon these general principles. As previously, it is convenient to subdivide the many possible applications into two groups: those that are characterised by the presence of lumped resonant mechanical elements and those characterised instead by the present of distributed-parameter resonant mechanical elements.

Applications in High Cycle Fatigue Testing

High Cycle Fatigue (HCF) mechanisms which occur as a result of sporadic resonant excitation of in-service mechanical components are difficult to replicate in the laboratory. Commercially available test machines typically realize cyclical fatigue loading in one of two ways; either resonant testing, which involves exciting the sample at resonance, usually as part of a time-contracted loading cycle; or a quasi-static approach, in which an oscillating stress is applied to the sample at low frequency with an amplitude equivalent to that occurring at resonance. Both of these schemes make assumptions about the relative criticality of different aspects of the load cycle to the determination and characterisation of component failure mechanisms: the first assumes that the behaviour of the specimen is insensitive to ‘time scaling’ of global conditions, i.e. contraction of the load cycle with respect to the period of resonant activity; the second that the strain rate experienced as a result of the HCF load being represented is unimportant. The relative validity of these two assumptions continues to be a subject of debate; however, the resonant scheme is certainly advantageous in a number of respects:

1. Strain rates experienced by the specimen are more closely matched to reality; this is of significance, since the ratio between the period of the applied strain and the timescales over which molecular diffusion and recovery processes take place are key determining factors in fatigue behaviour.

2. The quasi-static approach assumes a priori knowledge of the in-service component resonant loading regime that is in most cases not available or accessible.

3. The quasi-static loading method requires a point load to be applied to the specimen. This point load is generally not present in the real system that the test is designed to simulate. The resulting surface stresses and strains are therefore unrepresentative. Furthermore, if a quasi-static loading mechanism is operated at more than a few tens of Hertz, there are often unwanted dynamic effects associated with the inertia of the loading system. Moreover in the case that the mechanical system under test is very stiff, such quasi-static loading systems consume a great deal of power and have frequencies of operation limited for practical reasons to of order 10 Hz. Aero-engine component testing applications are an important subset of High Cycle Fatigue testing problems. The components that undergo HCF testing include jet engine turbine and compressor blades. Such testing is a vital part of the component development and certification process, however it is expensive and time-consuming. Moreover, in-service aero-components typically undergo high cycle loading in combination with a range of other different types of load (e.g. thermal, inertial, compressive etc.) which may occur simultaneously. The magnitude of such loads is such that the net effect of the superposition of loading effects cannot simply be determined by investigating their effects in isolation and assuming that they sum in a linear fashion i.e. such systems exhibit significant and complex non-linearly. Thus, it is desirable to test, where possible, a component under several applied loads, and for reasons of economy, as rapidly as possible. In aero-engine blade testing applications, the low upper limit on the frequency of quasi-static loading for HCF testing is unfortunate for three reasons; firstly because a flight-time load simulation programme cannot be contracted below around several hours, secondly because hardware is bulky, making it difficult to apply other important loads to the specimen (e.g. low-cycle compressive stresses), and thirdly because in order to perform the required number of load cycles in contracted-time tests, it is necessary to operate the HCF loading system continuously over the loading period. Such continuous operation places unrepresentative loads on the specimen.

4. The reduced power requirements of a resonant scheme. The power required to sustain resonant excitation of a test component is reduced by the quality factor of the resonance.

5. The reduced force requirements (i.e. reduced force per unit system displacement) of a resonant scheme mean that in most applications, non-contact loading schemes are feasible. Such non-contact schemes are advantageous (see 3) over point-load systems and provide a more realistic model of actual load characteristics.

Despite these advantages, resonant testing techniques are rarely implemented in practice since they are difficult to design and control. The mechanical resonances that it is desirable to excite and maintain in an HCF testing apparatus are typically very narrow—i.e. very high-Q. Conventional negative feedback controller arrangements which might otherwise be employed to control the apparatus are poorly suited to establishing and maintaining high-Q resonances. For aero-engine rotor blade testing applications the method of ‘Liquid Jet Excitation’ has recently been developed—see U.S. Pat. No. 6,679,121. However this system is complex to design and implement, and resonant excitation of the test specimens is via a contacting liquid jet, not a non-contact technique. Thus, there is required an improved means of achieving the resonant excitation of mechanical specimens for HCF testing applications.

The mechanical oscillator device described in general terms above provides the basis for a new type of HCF testing apparatus, capable of achieving robust, reliable resonant excitation of high-Q mechanical test specimens. The principles underlying the device enable the provision of integrated mechanical test machines which are more sophisticated, more effective, more straightforward to operate and cheaper to construct than prior art devices. Furthermore, in certain implementations of the device, two independent information streams are available to the operator—the resonance frequency of the mechanical component under test and the quality factor Q, of the resonance. Changes in both of these quantities may be monitored, the former being related to the stiffness of the component, the latter to the per-cycle loss. The loss information may be used to diagnose localised materials effects or the onset of material failure mechanisms such as fretting fatigue. Particular embodiments of the present invention may be used as a basis for component testing machines capable of implementing complex ‘accelerated simulation’ type tests (for example the modelling and application of the load cycle experienced by an aero-engine turbine blade in the course of a flight). Moreover, the mechanical oscillator device instrumentation (controller etc) is compatible with non-contact means of mechanical excitation of the mechanical structure 20 (e.g. via magnetic coupling of the component to an electrically excited coil or solenoid) avoiding the difficulties associated with direct-contact techniques and allowing other loads to be applied to a test specimen whilst the HCF excitation is present.

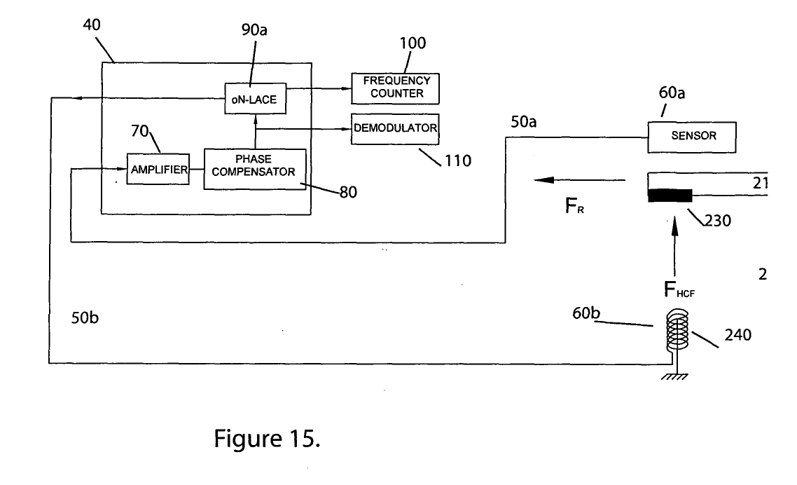

FIG. 15 shows a schematic (not to scale) arrangement for the mechanical testing of jet-engine turbine or compressor blade roots (and/or the corresponding blades). It should be noted that the exact detail of the implementation of the apparatus will depend strongly on the requirements and purpose of the test, and the geometry and material characteristics of the test specimen. Many possible variations are thus possible within the scope of the invention as claimed.

In the aircraft, aero-engine turbine/compressor blades may be friction mounted in a ‘disc slot’, or the disc and blades may be combined in a single component known as a blisk (or integrally bladed rotor/compressor). In the former case, the ‘roots’ of the blades have a certain form which may for example resemble a fir-tree—‘fir-tree’ roots, or a dove's tail—‘dovetail’ roots. This form is computed to maximize the life and performance of the root-disc interface. It is desirable to test the performance of blade roots. As shown in FIG. 15, a root 200 of a turbine or compressor blade 210 to be tested—the ‘sample’—is anchored in a spinning assembly 205 in a socket or slot 220 resembling that provided by the disc slot in the real engine, and is then excited at resonance by a force F_{HCF} applied at the tip of the blade 210 via a non-contact actuator coupling 60b. The non-contact actuator coupling 60b is driven by the mechanical oscillator controller 40 and may, for example, take the form of a solenoid 240 located at a fixed position below the spinning assembly 205, and magnetically coupled to a permanent magnet 230 (e.g. a Samarium Cobalt or Neodymium Iron Boron ceramic magnet) affixed to the distal end of the blade 210. Feedback from the blade 210 to the controller 40 is achieved via a sensor 60a. In addition to the HCF loading provided by the mechanical oscillator device 10, the testing apparatus may further be designed to apply other loads to the sample. Such other loads may include for example; a load to simulate centrifugal loading of the root 200-disc slot 220 interface that occurs as the blade 210 spins in the engine (provided in the arrangement of FIG. 15 by the spinning of the assembly 205), a load to simulate compressive stresses that occur at the root 200 as a result of thermal expansion of the disc, and thermal loads.

In use of the arrangement of FIG. 15, compressive loads F_{c} are applied (for example via a hydraulic actuator—not shown) and the assembly 205 is spun at some speed to simulate a centrifugal load F_{R}. One blade 210 is shown, but any number may be mounted on the central spinning ‘hub’ 205. As the blade 210 passes over the solenoid 240, the HCF excitation is applied by the mechanical oscillator. Such excitation may be applied every time the blade 210 passes over the solenoid 240 or as otherwise determined by the operator. Additionally, the blade root 200 and the region of disc and/or blade proximal to it may be heated. Heating (for example to the region 215) may be achieved by a variety of means for example, via an induction heating element (also not shown in FIG. 15).

The sensor 60a outputs a signal along input 50a to the controller 40 which operates as described previously. A demodulator 110 and a frequency counter 100 are provided and these are able to provide signals representative of, respectively, changes in the quality factor Q of the resonance (which indicates the per-cycle loss), and changes in the resonance frequency of the component being tested, (which indicates changes in the component stiffness).

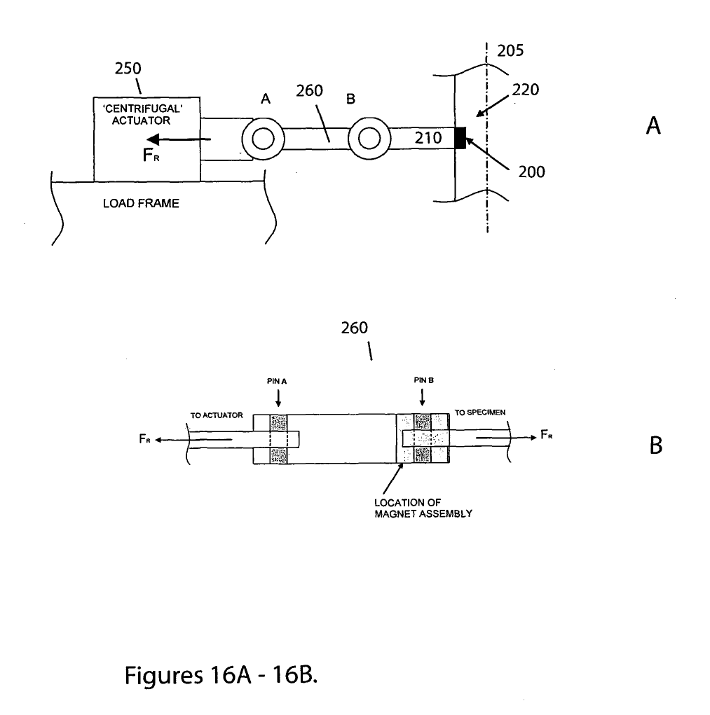

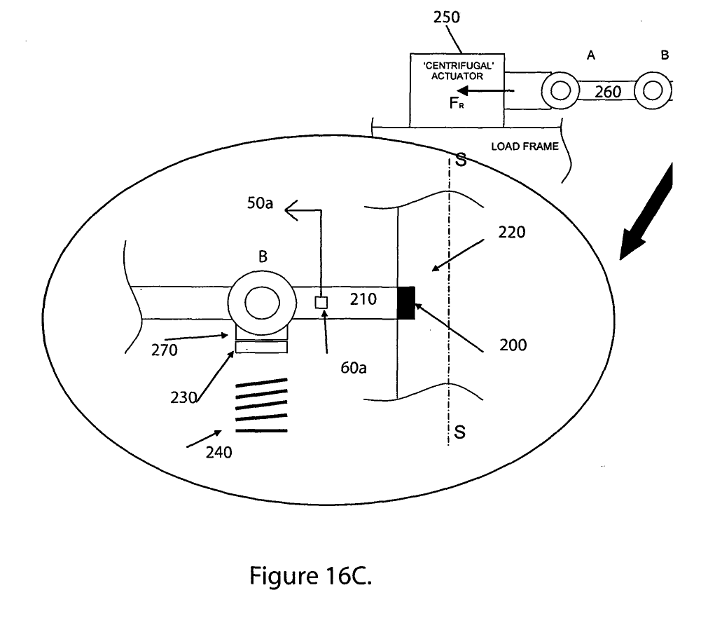

FIGS. 16A, B and C show a schematic arrangement of mechanical testing apparatus with functionality equivalent to that of FIG. 15. The figures are not to scale. Here, simulated centrifugal loading of the sample is achieved via a hydraulic actuator 250 which is connected to the blade 210 via an hydraulic connector 260, as shown in FIG. 16A. The hydraulic connector 260 is shown in more detail in FIG. 16B. As in FIG. 15, the sample ‘root’ 200 and the region proximal to it may be heated.

FIG. 16C shows schematically, detail of an example HCF sample actuation and sensing scheme for the arrangement of FIGS. 16A and 16B. As in FIG. 15, the blade 210 is actuated via the interaction of a solenoid 240 and a permanent magnet 230, the latter being mounted to the pin B (FIGS. 16A and 16B) via a thermally insulating material 270. The sensor component 60a, providing an electrical output to the mechanical oscillator controller 40, takes the form of a strain-gauge attached to the blade 210.

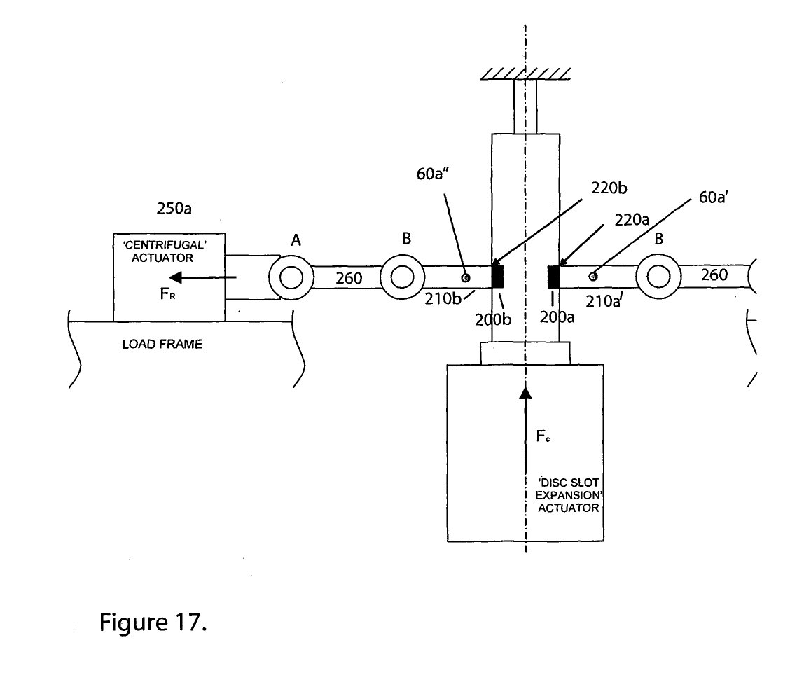

FIG. 17 shows how the elements of FIGS. 16A-C may be incorporated into an actual test machine. The diagram is not to scale. The roots 200a, 200b of two blades 210a, 210b are each mounted in respective slots 220a, 220b in a hub 205. A tensile stress, analogous to that which occurs due to centripetal acceleration of the blades in the real aircraft is provided to each blade 210a, 210b by hydraulic actuators 250a, 250b respectively. An actuator provides a compressive load F_{c} to replicate the compressive stresses experienced by the blade as a result of thermal expansion of the disc. High Cycle excitation of the blades 210a, 210b and blade roots 200a and 200b is achieved through the action of two implementations of a mechanical oscillator embodying the present invention (one for each blade) via two sensor/actuator configurations as depicted in FIG. 16C (one for each blade). Note that the actuator components of FIG. 16C are not shown in FIG. 17 for the sake of clarity.

Many possible variations of the arrangements of FIGS. 15-17 are possible in the context of the present invention. The actuator 60b at the input interface between the controller 40 and the blade 210 may differ from the non-contact magnetic actuation technique described, and the sensor 60a at the input interface to the controller 40 may be any viable device e.g. an optical detector, a stress or strain gauge or a piezoelectric transducer.

The arrangement of FIG. 17 allows for the HCF excitation of the samples 210a and 210b via two separate implementations of the mechanical oscillator device. This HCF loading is applied in conjunction with the tensile and compressive loads above described so as to adequately simulate the conditions experienced by the sample (blade) in a real aircraft engine. The frequency of operation of the mechanical oscillators incorporating the respective samples (blades) is directly related to their stiffness. Thus any changes in the stiffness of the blade—such as might be brought about by changes in the mechanical properties thereof which occur as a consequence of the loading cycle—may be detected or monitored via measurement of these frequencies. Moreover, any lossy failure processes—for example fatigue, failure, or crack nucleation will manifest themselves as changes in the quality factor or Q of the respective sample resonances—and may accordingly be detected or monitored via a demodulation and comparison of the input Vs output signals of the respective mechanical oscillator controllers.

The concepts outlined above in connection with FIGS. 15 to 17 can be used as a basis for other, similar arrangements. For example, a device to identify the frequency response characteristics of a mechanical component (for example an aeroengine turbine/compressor blade) may be implemented. Such a device would be based on a mode-selectable realisation of the mechanical oscillator and may operate in conjunction with a moveable sensor or sensor array, these concepts being outlined previously.

Application to Spin-Wave Delay-Line Coupled Mechanical Oscillators (SDLCMOs)

Another application of the general concepts introduced above is in the provision of a mechanical oscillator device wherein the mechanical structure includes one or more magnetic or magnetically doped or loaded micro or nano mechanical elements directly or indirectly coupled to a standing or propagating spin-wave (magnon) within a distributed-parameter magnetic spin system or ‘Spin-wave Delay-Line’ (SDL).

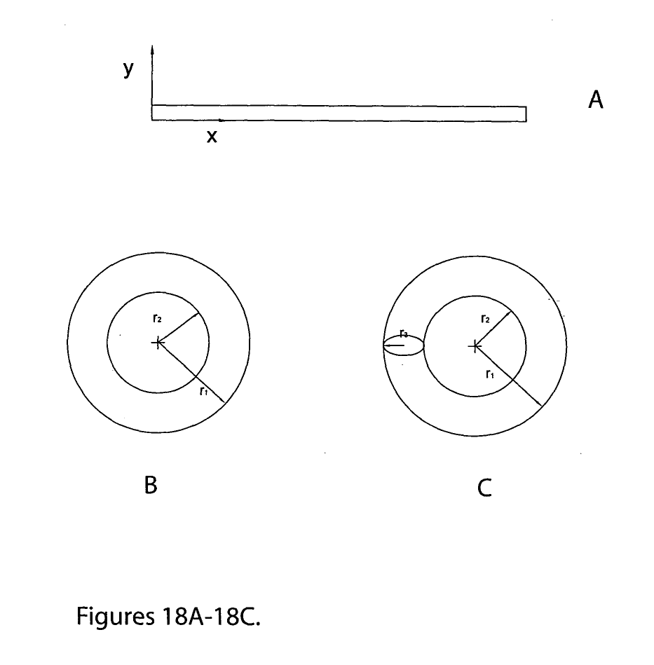

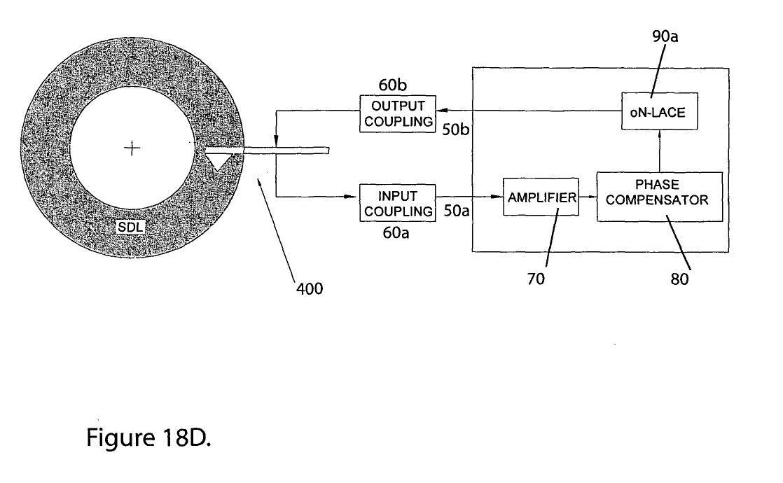

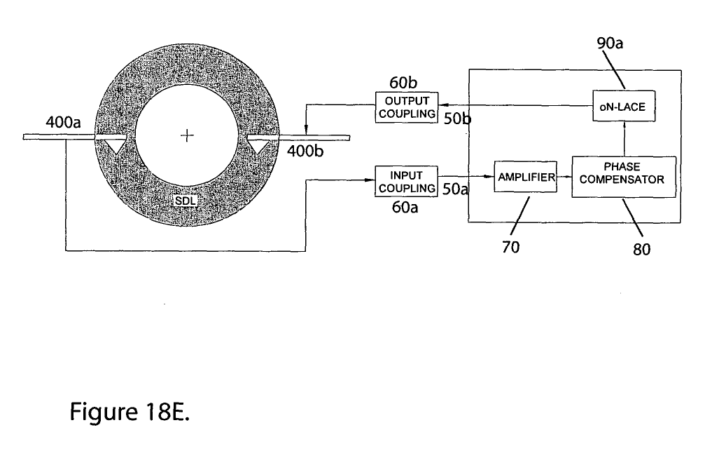

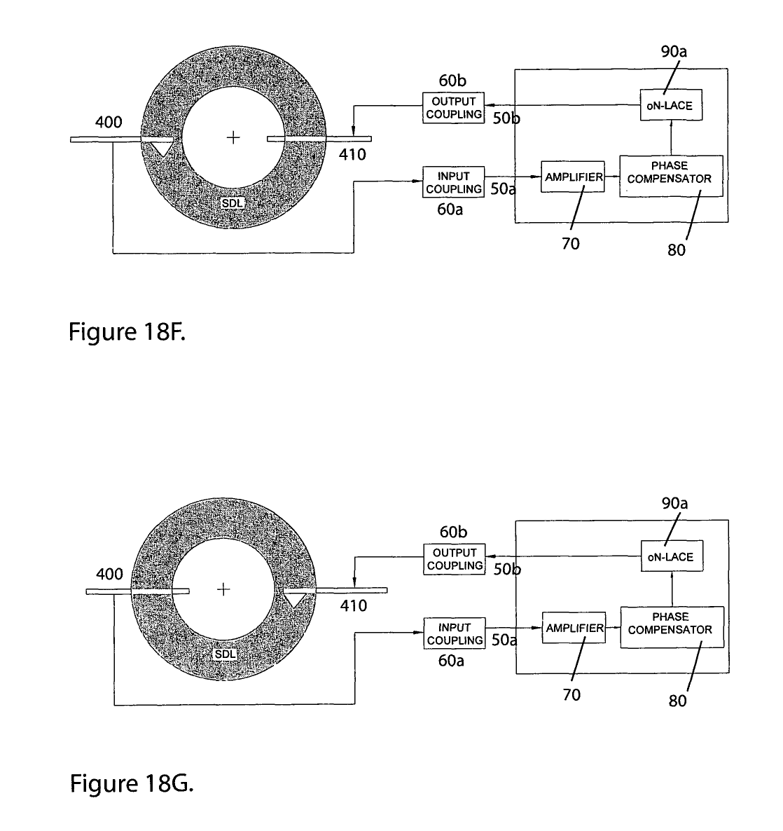

A Spin-wave Delay-Line (SDL) is defined in the present context as a magnetic transmission element with a characteristic dimension that is at least a substantial fraction of the wavelength of a spin-wave signal that propagates along it. Spin-wave delay-lines of any symmetry are possible in the present context. A first example is set out in FIG. 18A, wherein an SDL is shown which comprises a strip of magnetic material having 2D rectangular symmetry. FIG. 18B shows an SDL in the shape of a ring having 2D circular symmetry, and FIG. 18C shows a toroid having 3D circular symmetry. Delay-lines may be fabricated from any suitable magnetic material. In certain applications it may be desirable to fabricate the delay-line from a ferro- or ferri- magnetic material with a low or relatively low intrinsic spin-wave damping—for example Yttrium Iron Garnet (YIG) or Permalloy.

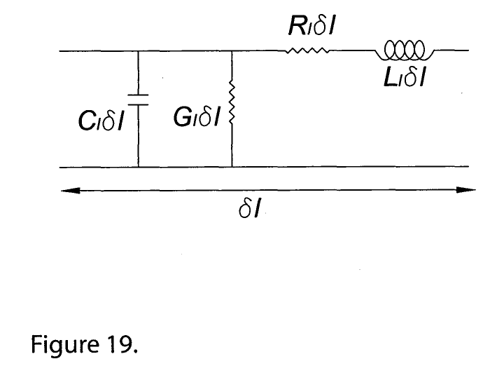

Any SDL may be described in terms of an incremental electrical equivalent circuit. For the purposes of illustration a one-dimensional line with rectangular symmetry is considered. An incremental length δl of such an SDL is shown in FIG. 19. The effective characteristic impedance Z₀(jω) of the line (defined as the ratio of two quantities conserved across line interfaces) is determined by its per-unit-length effective resistance, inductance, shunt conductance and shunt capacitance: R₁, L₁, G₁ and C₁ respectively:

$${Z}_{0} ( j ω ) = \sqrt{\frac{{R}_{l} + j ω {L}_{i}}{{G}_{l} + j ω {C}_{l} }} \qquad ( 4 )$$

R₁, L₁, G₁ and C₁ are (substantially non-linear) functions of frequency, the magnetic properties of the SDL material and the global and local external magnetic and thermal environments. In direct analogy with the familiar electrical transmission line case, the real part of the spin-wave delay-line characteristic impedance is related to its phase response, whilst the imaginary component is determined by its loss characteristics. The spin-wave propagation coefficient is of the form;

γ=α+jβ (5)

where β is a phase factor and α a loss coefficient.

The spin-wave delay-line is an example of a distributed-parameter magnetic system. Thus for a given SDL, an effective frequency-dependent magnetic input impedance Zᵢₙ(jω) may be defined which describes how readily a spin-wave of a given frequency propagates along the line. The magnetic input impedance of a given delay-line system is dependent on the characteristics of the line and the magnetic boundary conditions at its ends. Examples of practical magnetic SDL structures include ‘simple’ or ‘single-domain’ type delay-lines where the delay-line comprises a single magnetic domain of some length l (which may, for example be defined by two or more domain walls), ‘compound’ or multi-domain’ type lines, where the SDL is composed of two or more sections of line of differing characteristic impedance and ‘structured’ SDLs which have a single or multi-domain structure and incorporate lumped magnetic features.

In the context of Spin-wave Delay-Line Coupled Mechanical Oscillator (SDLCMO) implementations which embody the present invention, the incorporated SDL may be driven in two ways—the first ‘transmission mode’, involves distinct magnetic or magnetically doped or loaded micro or nano mechanical SDL interface elements, one coupled to the input 50a of the controller 40, the other coupled to the output 50b, separated spatially by some distance S (which may be a linear, radial, circumferential distance etc. depending on the geometry of the line). The coupling between the interface elements and the controller 40 may take several forms e.g. inductive, piezoelectric or capacitative. In operation, a propagating or standing spin-wave appears along or around the line between the input and output mechanical SDL interface elements and is directly or indirectly coupled to them, thus the SDL forms part of the mechanical oscillator signal path. Variants on this arrangement which also fall within the scope of the invention include those in which one micro or nano mechanical element provides either the input or output SDL interface and the other interface element takes some other form (for example a piece of electrical stripline). The second way in which SDLs may be driven in the context of the present invention—‘reflection mode’—uses a single input-output magnetic or magnetically doped mechanical SDL interface element. In such a reflection mode system, a spin-wave is modified or excited along the SDL via the input-output mechanical SDL interface element and in turn, the effective impedance which a coupling component (for example an inductive, capacitative or piezoelectric coupler) which connects the SDL interface element to the mechanical oscillator controller 40 is dependent on its interaction with the SDL. Thus, the magnetic properties of the SDL influence the operating frequency and amplitude of oscillation of the oscillator, but the signal path around the mechanical oscillator may be entirely non-magnetic. For the purposes of illustration, FIG. 18D shows an example of a example spur-coupled reflection mode SDL arrangement incorporating the features of the mechanical oscillator as already outlined and a mechanical interface element 400. In FIG. 18E, a transmission mode SDL implementation is shown, again incorporating those features of the invention as above described. In FIG. 18F a transmission mode SDL arrangement is depicted which incorporates one mechanical interface element 400 (input) and one non-mechanical one 410 (output) (for example a piece of electrical stripline). In FIG. 18G a series-coupled SDL arrangement is depicted which incorporates one mechanical interface element 410 (output) and one non-mechanical one 400 (input) (for example a piece of electrical stripline).

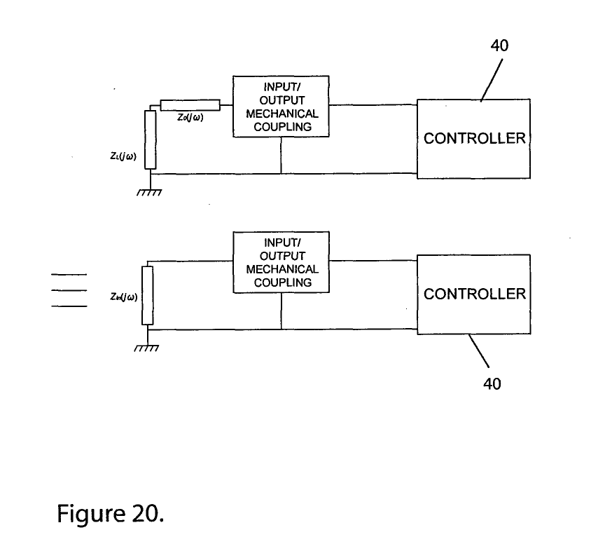

In general, spin-wave delay-lines exhibit a frequency dependent input/output phase response. The magnitude of the frequency response of their effective magnetic input impedance |Zᵢₙ(jω)| features a one or more minima and/or maxima. The exact form of the input impedance of the SDL is dependent on the detail of the system (i.e. multiplicity, type and arrangement of magnetic regions and elements incorporated and the external magnetic environment). In order to better describe the functioning of the SDLCMOs described herein, the example may be considered, of an SDL comprising a distributed-parameter magnetically homogeneous region of length l and effective characteristic impedance Z₀(jω), terminated by an effective magnetic ‘load’ Z_{L}(jω). In the physical magnetic system, Z_{L}(jω) may for example take the form of a magnetic domain wall and may take any real, imaginary or complex value including zero and infinity. A reflection mode implementation of the SDLCMO might be arranged as indicated in FIG. 20. The effective magnetic input impedance Zᵢₙ(jω) of the SDL of FIG. 20 may be written in the form:

$${Z}_{i n} ( j ω ) = {Z}_{0} ( j ω ) \frac{( {Z}_{L} ( j ω ) + {Z}_{0} ( j ω ) tanh γ l )}{( {Z}_{0} ( j ω ) + {Z}_{L} ( j ω ) tanh γ l )} \qquad ( 6 )$$

where the symbols are as defined in (4) and (5).

It should be noted that the expression of (6) only considers the frequency response characteristics of the SDL and does not take onto account those of the SDL mechanical interface elements (c.f. FIGS. 18A-G). In a practical instrument, the effective impedance presented by a magnetic system comprising an SDL and mechanical interface element(s) may have a strong dependence on the frequency response characteristics of the interface component(s). It may be the case that although the SDL itself is strongly multi-moded—i.e. many standing and/or propagating spin-wave modes exist—the nature of the interaction with the interface element(s) is such that the combined system—i.e. the mechanical structure—is effectively mono-modal.

In certain applications of the SDLCMO, it is arranged that as well as providing driving, amplitude regulation and amplification functions necessary for SDLCMO operation, the mechanical oscillator controller 40 presents some frequency-dependent effective impedance. This frequency dependent impedance may partly define the operating frequency of the oscillator or may provide modal selectivity.

The effective resonance frequency (ERF) of the SDLCMO may be co-incident with the resonance frequency of one or more SDL mechanical interface elements, the operating frequency of the incorporated SDL (i.e. a frequency characteristic of an active SDL spin-wave mode or propagating spin-wave) or some other advantageous frequency. In a particular implementation of the oscillator, the operating frequency is defined by an external signal which interacts with the SDL mechanical interface element(s) via the SDL. In measurement and control applications, for reasons of sensitivity and effective signal capture it may be arranged that such an external signal might appear as a modulation of a high frequency effect (for example a high frequency propagating or standing spin-wave) within the SDL which it is desirable to measure at a frequency at or around a resonant response of the SDL mechanical interface element(s).

Magnetic Resonance Tracking (MRT): Lumped Spin Oscillators

In a magnetic resonance tracking (MRT) implementation embodying the present invention, the mechanical system takes the form of a mechanical element or elements directly or indirectly interfaced with a lumped nuclear, proton or electron spin system, providing the basis for a range of new Magnetic Resonance Force Microscopy (MRFM) instruments.

The basic tool of Magnetic Resonance Force Microscopy (MRFM) is a micro-mechanical oscillating cantilever. In current state-of-the-art instruments this cantilever is generally ˜10 μm in length and typically fabricated from Silicon. Instruments vary in construction, but in the most basic scheme, a piece of magnetic material—or magnetic tip—is attached to the free end of the cantilever. This magnetic tip is generally approximately spherical or cone shaped and may for example comprise a solid particle of hard magnetic material (e.g. Samarium Cobalt) or a substrate (for example Silicon) sputtered with a soft magnetic Material (for example Cobalt Iron). The magnetic field at a position r measured from the centre of the tip is Bₜ(r). The cantilever is suspended above the magnetic sample in the presence of a homogenous D.C magnetic field B₅ and it is arranged that it oscillates at its mechanical resonance frequency ωₘ. The magnetic tip thus provides a means of magnetically coupling the sample to the cantilever. The force between sample and cantilever is related to the product of the magnetic moment (proton, electron, or nuclear) of the sample and the magnetic field gradient provided by the tip.

Making a measurement with the instrument involves observing the effect on the mechanical resonance frequency ωₘ of the cantilever of exciting a magnetic resonance (MR) in the sample. Magnetic resonance in the sample may be excited by application of a time-varying electromagnetic field, with a frequency ω_{L} equal to the Larmor frequency.

The Larmor frequency for a given spin population is determined by the appropriate gyromagnetic ratio γ (Table 1) and the applied magnetic field:

ω_{L}=γ|Bₜ(r)+Bₛ| (7)

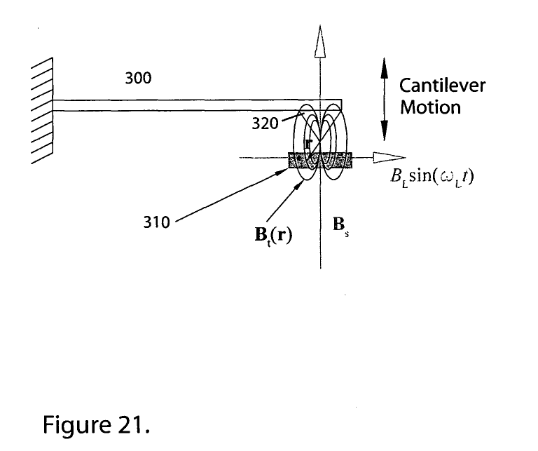

In a typical system ω_{L} is in the radio-frequency (RF) range and well outside the resonance response of the cantilever i.e. ωₘ<<ω_{L}. Thus, in order to couple a magnetic resonance to the cantilever, as well as an electromagnetic excitation at ω_{L}, a method of implementing a more slowly varying magnetic moment is required. This is typically achieved by amplitude or frequency modulation of the RF power with which the magnetic resonance is excited. FIG. 21 is a schematic diagram (not to scale) illustrating a possible arrangement of cantilever 300, sample 310 and magnetic tip 320 described above. Many other arrangements are possible, for example the cantilever axis may be arranged perpendicular to the plane of the sample. Although for clarity it is useful to consider just one particular implementation, the theory discussed is applicable to any instrument geometry.

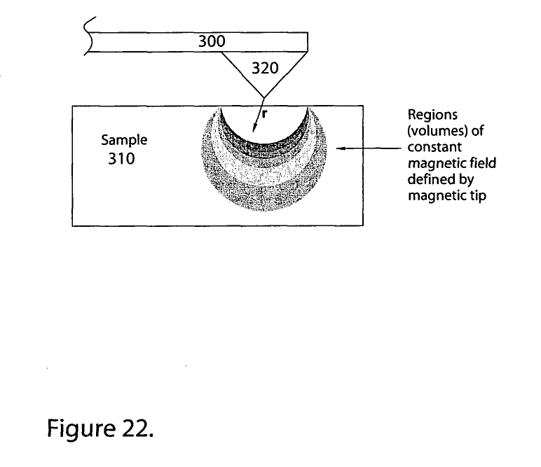

FIG. 21 also shows the three magnetic fields provided by the instrument: the DC applied magnetic field Bₛ, Bₜ(r) arising from the magnetic tip, and the AC magnetic field applied at the Larmor frequency B_{L} sin(ω_{L}t). Of these three fields the former two define the magnetic resonance frequency ω_{L} according to (7) and the latter excites the resonance. B_{L} sin(ω_{L}t) is typically realised by exciting a coil (not shown) in the vicinity of the sample 310 with a current I_{L} sin(ω_{L}t). The field gradient provided by the magnetic tip defines regions of constant magnetic field within the sample (FIG. 22). The spatial extent of these regions largely defines the spatial resolution of this type of microscopy: at any instant in time, magnetic resonance is only excited in the region of the sample for which the resonance condition (7) is met. Thus, as the mechanically resonant cantilever 300 sweeps up and down above the sample, so the resonant volume sweeps through it. Accordingly, the 3D region of sample interrogated by the instrument at any instant in time is determined by the location of the magnetic tip relative to the sample surface.

Variants on this set-up involve growing or depositing the sample on the cantilever 300 and employing a fixed magnetic tip (or array of tips). However, regardless of the exact detail of the implementation, the functions of the magnetic tip and thus the requirements thereof are preserved. In general, the more substantial the magnetic field gradient provided by the tip, the better the quality of the instrument. The current state-of-the-art instruments employ magnetic tips with field gradients of order 10⁶Tm⁻¹. The quality factor Q of the cantilever mechanical resonance is another major determining factor in the quality of the instrument. A high-Q cantilever of low stiffness and high natural frequency is desirable. A further key determining factor in microscope resolution is the correspondence between the mechanical resonance frequency of the cantilever 300 and the magnetic resonance excitation modulation. To achieve frequency matching, a servo-system is generally employed to detect and track the resonance frequency of the cantilever, this in turn drives the RF modulation. Within the closed-loop servo-system, a means of detecting the cantilever position is required; this usually takes the form of a high frequency capacitative or inductive position gauge or laser interferometer impinging on the cantilever 300. Both the servo-loop and any interferometer are non-trivial to design and set up. The former is susceptible to dynamic tracking errors if incorrectly implemented; the latter to malfunction owing to parasitic interference effects deriving from reflections from other surfaces. Such difficulties are especially pronounced if the laser is of high quality and has a long temporal coherence length. Various devices including RF modulation of the laser have been invented to circumvent these difficulties but none remove the issues at root cause. Moreover, optical detection techniques require bulky equipment and cause difficulties in low-temperature instruments: they are a source of thermal noise and demand a line of sight from laser to cantilever.

It should be noted that aside from the RF modulation schemes mentioned above, latterly, more sophisticated means of coupling magnetic resonance in the sample to the cantilever mechanical resonance have been proposed and implemented. Typically these techniques (for example the ‘interrupted oscillating cantilever-driven adiabatic reversal’ (iOSCAR) protocol and related techniques) exploit adiabatic inversion of spins in the sample to make a measurement. In general, the cantilever motion is the low frequency driver in the inversion process. Whilst these techniques are advantageous over simple modulation schemes, they are not without fundamental flaws. Firstly, their performance limits are determined by a lock-in detection based feedback loop. Such feedback schemes are inherently badly suited to controlling high-Q systems and exact correspondence between the magnetic resonance frequency and the modulation signal is not assured. The result is a signal that is strongly dependent on the bandwidth of the lock-in detection. Additionally, in order to satisfy the requirements of adiabatic rapid passage, the effective signal acquisition rates achieved with these techniques are very low and there are inherent measurement errors or uncertainties brought about by the fact that perfectly adiabatic spin inversion is not practically realisable—only infinitely slow inversion is truly adiabatic with the validity of the adiabatic assumption being related to the ratio of the spin precession rate ω_{L} to the inversion rate (typically ωₘ).

TABLE 1

| | Gyromagnetic Ratio/MHzT⁻¹ |
|---|---|
| Neutron | 29.16 |
| Proton | 42.58 |
| Electron | 28024.95 |

The principles outlined herein provide the basis for a novel type of self-tracking MRFM instrument which, in a particular implementation, eliminates the need for a separate instrumentation system to detect and measure cantilever displacement.

Applications in MRFM Instrumentation: Indirectly Spin-Mechanically Coupled Systems

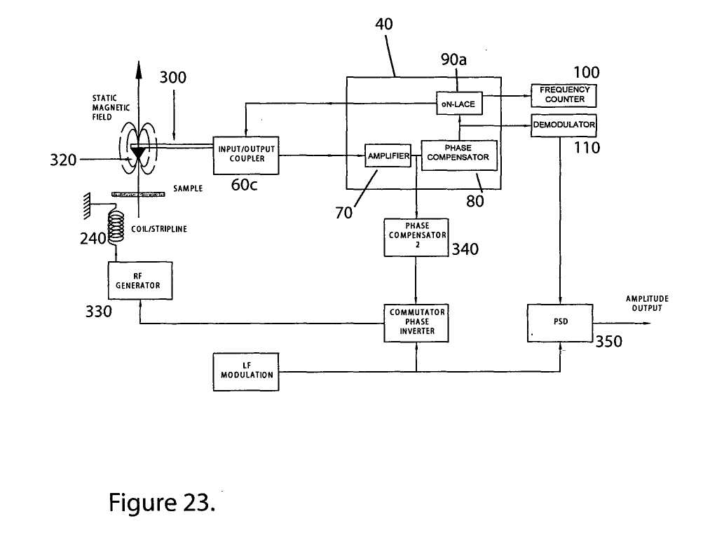

FIG. 23 shows an MRFM in which cantilever control and signal readout are achieved using the mechanical oscillator principles outlined above. In the most preferred embodiment of the instrument, the cantilever 300 is driven directly via a combined input-output coupler 60c (which may for example take the form of a piezoelectric or inductive transducer), but other drive schemes, including those incorporating a separate (e.g. optical) cantilever displacement detection scheme are also possible. The mechanical oscillator instrumentation operates at ωₘ, the resonance frequency of the cantilever 300. A radiofrequency (RF) generator 330 operating at the magnetic resonance (MR) frequency is amplitude modulated at the cantilever frequency ωₘ by extracting a signal from the output of the amplifier 70 in the controller 40. The extracted signal is a modulation signal which passes through a second phase compensator 340 (that is, distinct from the phase compensator 80 in the controller 40) which has the function of ensuring that the MR and cantilever drives are phase-aligned. The relative phase of the MR and cantilever drive signals is switched between 0 and 180 degrees at a Phase Sensitive Detector (PSD) 350 via the commutator (phase inverter). The phase inversion is provided by the action of a low frequency (LF) modulator and a commutator (phase inverter). The PSD modulation frequency ω_{PSD} takes a value,

$${ω}_{PSD} < \frac{{ω}_{m }}{Q} , \qquad ( 11 )$$

where Q is the cantilever quality factor. Accordingly, the PSD locks in to the signal components in the demodulator at the PSD 350 modulation frequency.

The frequency counter 100 detects the frequency of oscillation of the cantilever 300 and, thus, shifts in this frequency brought about by interaction of the magnetic tip 320 with magnetic resonance in the sample 310. The demodulator 110 provides an output proportional to the amplitude of oscillation of the cantilever which may accordingly be used to detect changes in the quality factor (Q) of the cantilever resonance brought about by magnetic resonance absorption in the sample 310.

The mechanical oscillator controller 40 incorporates an optimal non-linear-amplitude control element (oN-LACE) 90a as described above. The particular characteristics of the oN-LACE 90a makes the MRFM instrument of FIG. 23 superior over conventional MRFM control systems both in terms of ease of implementation, resolution and speed. In particular a new generation of ultra-fast, ultra-high resolution MRFM instruments may be envisaged, with a temporal resolution determined by the mechanical response characteristics of a high-Q micro or nano-mechanical cantilever rather than the temporal response of a comparatively slow control-loop.

Applications in MRFM Instrumentation: Directly Spin-Mechanically Coupled Systems

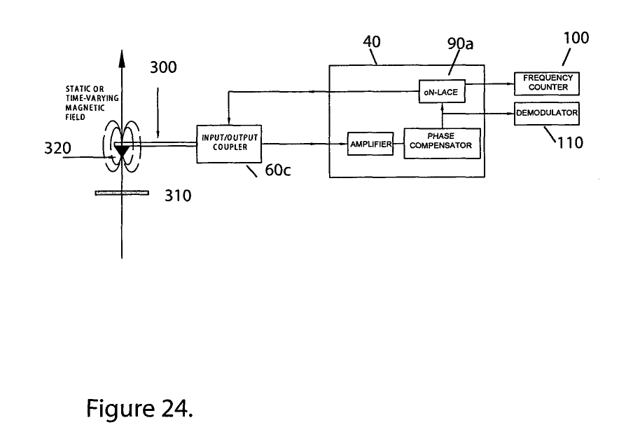

As well as the MRFM instrumentation described in connection with FIG. 23, an MRFM instrument in which one or more micro or nano-mechanical resonant elements with resonance frequencies in the MHz or GHz range are directly coupled to magnetically resonant spin populations can also be implemented. This arrangement is shown in FIG. 24. In FIG. 24, the cantilever, tipped with a magnetic element 320, is driven at the MR frequency, which is co-incident with its mechanical resonance frequency (or one of its mechanical resonance frequencies if there are several) via the input/output coupler 60c above the sample 310. The output from the input/output coupler 60c is input to the controller 40 via a low-noise amplifier and feedback to the cantilever completed via a phase compensator and oN-LACE 90a. The frequency counter 100 detects the frequency of oscillation of the cantilever 300 and thus shifts in this frequency brought about by interaction of the magnetic tip 320 with magnetic resonance in the sample 310. The demodulator 110 provides an output proportional to the amplitude of oscillation of the cantilever which may accordingly be used to detect changes in the quality factor (Q) of the cantilever resonance brought about by magnetic resonance absorption in the sample 310.

Other Types of Magnetic Instrumentation

As well as the instruments described above, in which MR or spin-waves are excited, modified or detected (or a combination of these) directly via a magnetic or magnetically loaded or doped micro or nanomechanical element, a further class of instrument in which free oscillations of one or more magnetic or magnetically loaded or doped mechanically resonant element(s) are entrained by resonant lumped spin system or spin-waves propagating in a spin-wave delay-line is made possible by the techniques and arrangements described herein. In such an instrument, a sample spin population or spin-wave delay-line would be pulse-excited by an external signal, and the resulting oscillating-magnetic signal coupled to at least one mechanical oscillator controlled micro or nanomechanical element with a resonance frequency proximal to: in the case of the lumped spin system, the Larmor frequency and, in the case of the spin-wave delay-line, a frequency characteristic of the excited spin-waves. Entrainment of the mechanical element would give rise to a measurable shift in the operating frequency of the mechanical oscillator or, equivalently a change in the beat frequency between the mechanical frequency and the external pulse signal. Such instruments would not only provide new insight in to MR and spin-wave phenomena but vehicles for the study of synchronization phenomena in non-classical systems.

As well as the specific mechanical oscillator implementations described above, the concepts underlying the present invention have a wide range of other applications. For example:

Force, Stress and Strain Gauges

Mode-tracking implementations of the mechanical oscillator technology provide the basis for macro, micro or nano-mechanical force, stress and strain gauges, or arrays of such gauges. Operation is based on monitoring the operating characteristics (frequency and/or amplitude of operation) of a mechanical oscillator incorporating a lumped or distributed-parameter macro, micro or nano mechanical element coupled to, or otherwise influenced by the force, stress or strain which it is desirable to measure.

Displacement, Velocity and Acceleration Sensors

Mechanical oscillator devices in accordance with the present invention provide the basis for macro, micro or nano-mechanical displacement, velocity and acceleration sensors, or arrays of such sensors. Operation is based on monitoring the operating characteristics (frequency and/or amplitude of operation) of a mechanical oscillator incorporating a lumped or distributed-parameter macro, micro or nano mechanical element coupled to, or otherwise influenced by the displacement, velocity or acceleration which it is desirable to measure.

Tuneable Frequency References and Parametric Amplifiers

Mode-tracking implementations of mechanical oscillator devices in accordance with embodiments of the present invention provide the basis for high-stability, tuneable frequency references and parametric amplifiers, the frequency determining component of which takes the form of a micro or nano-mechanical element which may be damped or loaded (by for example charge coupling, or the application of an external magnetic field to a magnetically doped element) to achieve tuning.

Mechanical Logic Elements

Other implementations of mechanical oscillator devices in accordance with embodiments of the present invention provide the basis for micro or nano-mechanical logic, information processing and storage elements. High-Q micro or nano-mechanical lumped or distributed-parameter mechanical processing elements may be manipulated rapidly and with a high degree of precision and robustness by using a device incorporating the controller as outlined above. Furthermore, modal selectivity may be exploited in conjunction with distributed-parameter mechanical systems to achieve high-functionality, compact mechanical processing systems the likes of which are inaccessible to the current state-of-the-art in conventional mechanical oscillator control technology. Certain SDLCMO implmentations of the mechanical oscillator devices are appropriate for the realization of novel ‘spinmechatronic’ logic, information processing and storage structures.

Ultrasensitive Mass, Density, or Charge Measurement Devices

Still further implementations of mechanical oscillator devices in accordance with embodiments of the present invention provide the basis for macro, micro or nano-mechanical mass, density or charge measurement devices, or arrays of such devices. Operation is based on measuring changes in the operating characteristics (frequency and/or amplitude) of a mechanical oscillator mediated by a change in the effective mass or effective stiffness of a macro, micro or nanomechanical element brought about by mass or charge loading, or a change in density of, for example, a flowing or stationary fluid which forms part of the mechanical structure.

Spectrometers and Sensors

Other implementations of mechanical oscillator devices in accordance with embodiments of the present invention provide the basis for spectrometers, sensors or similar instruments incorporating micro or nanomechanical elements, operated resonantly and coated with species-selective chemical compounds/biological molecules etc. Sensor functionality may be achieved by measuring changes in the operating characteristics (frequency and/or amplitude) of the oscillator mediated by changes in the effective mass or effective stiffness mechanical element(s).

Micro and Nanoscale Automation

Yet further implementations of mechanical oscillator devices in accordance with embodiments of the present invention provide the basis for robust, high speed nano or micro mechanical manipulators which might incorporate functional electronic, magnetic, optical, acoustic, chemical or biological components.

Destructive and Non-Destructive Mechanical Testing Apparatus

In other implementations of mechanical oscillator devices in accordance with embodiments of the present invention, destructive and non-destructive mechanical testing apparatus may be provided. The apparatus may be macro, micro or nanoscale and may be designed to investigate a wide range of tribological, fatigue and fault phenomena:

Although a specific embodiment of the present invention has been described, it is to be understood that various modifications and improvements could be contemplated by the skilled person.

### Appendix A: Mechanical Oscillator.

1 Description of the non-linear amplitude control element (N-LACE)

In this Section we offer a detailed description of the non-linear amplitude control element (N-LACE) integral to the mechanical oscillator invention.

For the purposes of analysis, it is useful to consider N-LACE functionality separately from that of the rest of the controller. The model of FIG. A1A is equivalent to that of FIG. 5C (reproduced in FIG. A1B) but here, the mechanical oscillator controller is represented by two complex, frequency dependent elements: G_{NL} representing the N-LACE and H which accounts for the remainder of the functional elements of the controller. In this model, H is assumed to be entirely linear in ν₁(t) thus, with reference to the figure, the input to the N-LACE ν(t), is a linear function of ν₁(t) whilst the N-LACE, output i(t) is a non-linear function of ν(t).

1.1 Functional Overview of the N-LACE

The non-linear amplitude control element (N-LACE) provides an amplitude regulated feedback signal i(t) to drive the mechanical arrangement.

The output of the mechanical arrangement—ν₁(t) (FIG. A1A)—is a continuous periodic energy signal with a spectral component s(t) at the effective resonance (operating) frequency ω₀ of the mechanical oscillator. The time-period T characteristic of s(t) is given accordingly by:

$$T = \frac{2 π }{{ω}_{0}} . \qquad ( A1 )$$

The signal s(t) is isolated from ν₁(t) (e.g. by filtering and subsequent phase-compensation) so that the signal arriving at the input to the N-LACE is of the form

ν(t)=As(t−τ₁), (A2)

where A is a constant and τ₁ a time-constant to account for inherent or imposed time delay and/or phase shift in the signal path. The feedback signal generated by the N-LACE in response to ν(t) is of the form:

i(t)=a_{NL}(ν(t−τ₂)). (A3)

where

τ₂=τ₁+τ (A4).

and τ is a time delay characteristic of the input-output conversion in the N-LACE which may or may not be frequency dependent. The instantaneous dynamic gain of the N-LACE is defined for any instantaneous signal input ν(t₁):

$${g}_{d} ( {t}_{1} ) = \frac{\partial i ( {t}_{1} + τ )}{\partial v ( {t}_{1} )} . \qquad ( A5 )$$

It should be noted that the ‘dynamic gain’ (defined here in conjunction with (A5) and used subsequently) is not a ‘gain’ in the conventional dimensionless sense, but a transconductance.

In the most general implementation of the mechanical oscillator, the function α_{NL}(ν(t)) which describes the N-LACE is an arbitrary non-linear function. However, in a particular preferred embodiment of the N-LACE, the function α_{NL}(ν(t)) has particular advantageous characteristics. From henceforth, a non-linear amplitude control element with such particular advantageous characteristics will be referred to as an optimal non-linear amplitude control element or oN-LACE.

### 1.2 Optimal N-LACE Characteristics

In this Section we describe the characteristics of an optimal non-linear amplitude control (oN-LACE) which features in certain preferred embodiments of the mechanical oscillator.

When at time t₁ the instantaneous amplitude of the oN-LACE input signal ν(t₁) is between certain preset fixed ‘positive’ and ‘negative’ thresholds the corresponding output i(t₁+τ) of the oN-LACE is approximately equivalent to a linear amplifier with a gain that is—in the most general case—dependent on the polarity of the signal. For a given oN-<LACE implementation, the ‘positive’ and ‘negative’ thresholds are respectively

$$+ \frac{{B}_{1}}{{K}_{01}} and - \frac{{B}_{2}}{{K}_{02}}$$

where B₁, B₂ are any real, non-negative integers (so long as in a given realization either B₁ or B₂ is non-zero) and K₀₁ and K₀₂ are real non-zero positive integers equal to the small-signal (SS) dynamic gains for positive and negative ν(t) respectively:

$$\begin{matrix}{g}_{{dSS}^{+}} ( {t}_{1} ) = {K}_{01} = \frac{\partial i ( {t}_{1} + τ )}{\partial v ( {t}_{1} )} {\vert}_{ {SS}^{+}} , & ( A6a ) \\ {g}_{{dSS}^{-}} ( {t}_{1} ) = {K}_{02} = \frac{\partial i ( {t}_{1} + τ )}{\partial v ( {t}_{1} )} {\vert}_{{SS}^{-}} . & ( A6b )\end{matrix}$$

n this signal regime, the output of the oN-LACE is described by:

i(t₁+τ)=K₀₁ν(t₁) for sgn{ν(t₁)}=1,

i(t₁+τ)=K₀₂ν(t₁) for sgn{ν(t₁)}=−1. (A7)

Note that the relative polarities of the oN-LACE input and output signals are arbitrarily defined. In the most preferred embodiment of the oN-LACE, at least one of K₀₁ and K₀₂ is a large, positive, real constant. Equation (A7) describes the ‘quasi-linear amplification regime’ or ‘small-signal amplification regime’ of the oN-LACE.

If at time t₁ the instantaneous amplitude of ν(t₁) is positive and its magnitude equals or exceeds the threshold

$$\frac{{B}_{1}}{{K}_{01}}$$

and/or the instantaneous amplitude of ν(t₁) is negative and its magnitude equals or exceeds the threshold

$$\frac{{B}_{2}}{{K}_{02}} ,$$

the oN-LACE operates in a ‘strongly non-linear’ or ‘large-signal’ regime. In the most preferred embodiment of the oN-LACE, the dynamic gain in the large-signal (LS) regime is zero regardless of the polarity of the signal ν(t₁):

$${g}_{dLS} ( {t}_{1} ) = \frac{\partial i ( {t}_{1} + τ )}{\partial v ( {t}_{1} )} {\vert}_{LS} = 0. \qquad ( A8a )$$

In a general embodiment of the oN-LACE, the large-signal dynamic gain g_{dLS}(t) is approximately zero regardless of the polarity of the signal ν(t₁) i.e:

$${g}_{dLS} ( {t}_{1} ) = \frac{\partial i ( {t}_{1} + τ )}{\partial v ( {t}_{1} )} {\vert}_{LS} \approx 0. \qquad ( A8b )$$

The most preferred embodiment of the optimal non-linear amplitude control element features a large-signal regime in which the amplitude of the oN-LACE output i(t₁+τ) takes a constant value +B₁ if at time t₁ the instantaneous amplitude of ν(t₁) is positive, and a constant value −B₂ if the converse is true. This behaviour is summarized by:

$$if \vert v ( {t}_{1} ) \vert \geq \frac{{B}_{1}}{{K}_{01}} and sgn [ v ( {t}_{1} ) ] = 1 , \vert i ( {t}_{1} + τ ) \vert = + {B}_{1} , \\ whilst if \\ \vert v ( {t}_{1} ) \vert \geq \frac{{B}_{2}}{{K}_{02}} and sgn [ v ( {t}_{1} ) ] = - 1 , \vert i ( {t}_{1} + τ ) \vert = - {B}_{2} . \qquad ( A9 )$$

In the special case that B₁=B₂=B and K₀₁=K₀₂=K₀(A9) becomes:

$$if \vert v ( {t}_{1} ) \vert \geq \frac{B}{{K}_{0}} and sgn [ v ( {t}_{1} ) ] = 1 , \vert i ( {t}_{1} + τ ) \vert = + B , \\ whilst if \\ \vert v ( {t}_{1} ) \vert \geq \frac{B}{{K}_{0}} and sgn [ v ( {t}_{1} ) ] = - 1 , \vert i ( {t}_{1} + τ ) \vert = - B \qquad ( A10 )$$

and a symmetrical oN-LACE input signal ν(t₁) results in a symmetrical output function i(t₁+τ). Between the quasi-linear and strongly non-linear signal regimes of the oN-LACE there is a ‘transitional’ signal region or ‘transition region’ (T). In this region, the behaviour of the non-linear amplitude control element is neither quasi-linear nor strongly non-linear. In the most preferred embodiment of the oN-LACE the transition region is negligibly wide.

FIG. 6 illustrates the most preferred input-output characteristics of the oN-LACE for the case that: B₁=B₂=B and K₀₁=K₀₂=K₀ (A10); there is no transitional (T) signal regime; the small-signal (SS) dynamic gain is independent of |ν(t₁)| and the large-signal (LS) dynamic gain is zero (A8a).

Three key features of the oN-LACE are: Feature 1: a sharp transition between the quasi-linear (small-signal) and strongly non-linear (large-signal) regimes effected by the instantaneous signal magnitude |ν(t₁)| exceeding a pre-determined threshold, the value of which may or may not be dependent on the polarity of the signal (c.f. (A9), (A10)); Feature 2: a narrow and preferably negligibly wide transitional signal regime; Feature 3: approximately instantaneous transition between quasi-linear and strongly non-linear regimes. Feature 3 is equivalent to the oN-LACE having capacity to respond to change in the amplitude (and frequency) of the instantaneous input signal ν(t₁) on a timescale typically significantly shorter than the characteristic signal period T i.e the oN-LACE has a certain amplitude temporal resolution Δτ<<T. Furthermore, with a particular implementation of the oN-LACE described in the context of the mechanical oscillator invention it may be arranged that the instantaneous amplitude of the oN-LACE output i(t₁) corresponds approximately instantaneously to that of the input i.e. if desirable, it may be arranged that the time-constant r defined in (A4) is negligibly small. Alternatively and more generally, the oN-LACE is designed such that a certain known time-delay τ (which may or may not be frequency dependent) exists between oN-LACE input and corresponding output; in such a system an oN-LACE input ν(t₁) gives rise to an output i(t₁+τ) with amplitude temporal resolution Δτ independent of τ. It is an important and particular feature of the mechanical oscillator invention that the amplitude control achieved via the oN-LACE is not of a slow-acting ‘averaging’ type. Moreover, changes in the centre frequency or dominant frequency component of the input signal ν(t₁) may be resolved on a time-scale comparable with the amplitude temporal resolution Δτ; i.e. the frequency content of a general output signal i(t₁+τ) corresponds to the instantaneous frequency content of the input ν(t₁).

1.3 oN-LACE Signal Characteristics: Symmetrical Input Signal

In this Section we discuss the input-output signal characteristics of the oN-LACE for the special case that the input is a symmetrical, sinusoidal waveform with frequency ω₀ and period of oscillation T (A1). Asymmetrical input signals are described in Section 1.4. In accordance with the description at the beginning of Section 1.1 and with reference to (A3) and (A4) we assume that the oN-LACE input signal is a time-shifted, linearly amplified derivative of an electrical signal s(t): a monochromatic signal at the effective resonance frequency of the oscillator ωₙ. For clarity in this Section we reference all signals relative to time t defined by s(t):

s(t)=α sin ω₀t, (A11a)

ν(t+τ₁)=A sin ω₀t. (A11b)

The oN-LACE input signal (A11b) is depicted in FIG. A2A. In the analysis that follows, we consider the particular case that the positive and negative amplitude thresholds characteristic of the oN-LACE have equal magnitude (i.e. (A10) holds), that the small-signal regime is characterized by a certain constant dynamic gain K₀ independent of the polarity of the signal ν(t+τ₁), that the large-signal dynamic gain is zero and that there is no transitional signal regime.

In the quasi-linear amplification regime, the output signal from the oN-LACE is given by a time-shifted, linearly amplified version of the input signal:

i(t+τ₂)=AK₀ sin ω₀t. (A12)

FIG. A2B shows the output i(t+τ₂) of the non-linear amplitude control element for the case that for the entire period T of the signal ν(t+τ₁),

$$\vert v ( t + {t}_{1} ) \vert \leq \frac{B}{{K}_{0}} ,$$

i.e. the oN-LACE operates continuously in the quasi-linear amplification regime.

FIG. A2C shows the output from the non-linear control element i(t+τ₂) for the case that during around half of the period of the input signal T,

$$\vert v ( t + {τ}_{1} ) \vert > \frac{B}{{K}_{0}} .$$

The function of the oN-LACE is to amplify the received monochromatic energy signal ν(t+τ₁) at ω₀ (in general an amplified, time-shifted, phase compensated version of a raw electrical signal s(t)), and redistribute its RMS power over harmonics of the operating frequency of the mechanical oscillator ω₀. In what follows we compare the Fourier series describing oN-LACE input and output signals and give an insight into how the distribution of power is affected by the amplitude A of the input signal ν(t+τ₁). We derive the Fourier representation of the output signal of the oN-LACE corresponding to a symmetrical sinusoidal input of general amplitude A assuming oN-LACE characteristics as described above.

FIG. A3 shows a single positive half-cycle of ν(t+τ₁) and, superimposed (bold), a single positive-half cycle of a corresponding oN-LACE output i(t+τ₂). The limiting values of the oN-LACE output, ±B are indicated. We assume that the ratio A/B is such that for a fraction 1−α of a quarter-cycle,

$$\vert v ( t + {τ}_{1} ) \vert \geq \frac{B}{{K}_{0}}$$

i.e. for the positive half-cycle

$$\vert v ( t + {τ}_{1} ) \vert \geq \frac{B}{{K}_{0}} for \frac{α T}{4} < t + {τ}_{1} \leq \frac{T}{4} ( 2 - α )$$

whilst for the negative half-cycle

$$- \vert v ( t + {τ}_{1} ) \vert \leq - \frac{B}{{K}_{0}} for \frac{T}{4} ( 2 + α ) < t + {τ}_{1} \leq \frac{T}{4} ( 4 - α ) .$$

The constant B and angle α are related by

$$α = \frac{2}{π} a sin ( \frac{B}{{AK}_{0}} ) . \qquad ( A13 )$$

For all possible values of AK₀, the periodicity and symmetry of i(t+τ₂) are preserved. Thus the Fourier series describing i(t+τ₂) is of the form

$$i ( t + {τ}_{2} ) = {b}_{1} sin {ω}_{0} ( t + {τ}_{2} ) + {{\sum }_{3}}^{∞} {b}_{n} sin n {ω}_{0} ( t + {τ}_{2} ) \\ n = 2 m + 1 for m = 1 , 2 , 3 , … , \qquad ( A14 )$$

with coefficients

$$\begin{matrix}{b}_{1} = {AK}_{0} ( α - \frac{1}{π} sin ( π α ) ) + \frac{4 B}{π} cos ( \frac{π}{2} α ) , & ( A15a ) \\ {b}_{n} = \frac{2 {AK}_{0}}{π} \{ \begin{matrix}\frac{1}{( 1 - n )} sin ( ( 1 - n ) \frac{π}{2} α ) - \\ \frac{1}{( 1 + n )} sin ( ( 1 + n ) \frac{π}{2} α )\end{matrix} \} + \frac{4 B}{n π} cos ( n \frac{π}{2} α ) . & ( A15b )\end{matrix}$$

For constant B and increasing AK₀, the fraction a decreases and i(t+τ₂) tends to a square wave with fundamental frequency component ω₀. FIGS. A2D-G illustrate i(t+τ₂) for increasing A. FIG. A2G illustrates the waveform for the limiting case AK₀>>B, α→0. When the latter condition is fulfilled, the power in the signal i(t+τ₂) at the fundamental frequency ω₀ is given by

$${P}_{0} = {( \frac{4 B}{π} )}^{2} . \qquad ( A16 )$$

Whilst the total power is the summation

$$P = {P}_{0} + {{\sum }_{3}}^{∞} {( \frac{4 B}{n π} )}^{2} \\ n = 2 m + 1 for m = 1 , 2 , 3 , … \qquad ( A17 )$$

The summation (A17) has a finite limit:

P=2B². (A18)

Thus as AK₀→d where d>>B and α→0, the ratio P₀/P tends to a finite limit S₁:

$${S}_{l} = \frac{8}{{π}^{2}} = 0.8106 . \qquad ( A19 )$$

1.4 oN-LACE Signal Characteristics: Asymmetrical Input Signal

The Fourier analysis of the previous Section may be extended to input waveforms of lower symmetry. For the purposes of illustration we consider the simple asymmetric input function depicted in FIG. A4 for which a single signal period T comprises a symmetrical positive cycle of duration βT and peak amplitude A₁ and a symmetrical negative cycle of duration (1−β)T of peak amplitude A₂ where β≠0.5. We derive the Fourier representation of the asymmetric output signal i(t+τ₂) of the oN-LACE in the large-signal regime for the particular case that the positive and negative amplitude thresholds characteristic of the oN-LACE have magnitude B₁ and B₂ respectively, that the small-signal regime is characterized by a certain constant dynamic gain K₀ independent of the polarity of the input signal ν(t₁+τ₁), that the large-signal dynamic gain is zero and that there is no transitional signal regime.

In the limit of large AK₀ i.e. in the large-signal regime, i(t+τ₂) tends to an asymmetric square wave ω₀ as depicted in FIG. 5. Thus, the Fourier series describing i(t+τ₂) is of the form

$$i ( t + {τ}_{2} ) = {b}_{0} + {{\sum }_{1}}^{∞} {b}_{m} cos m {ω}_{0} ( t + {τ}_{2} ) \\ m = 1 , 2 , 3 , … \qquad ( A20 )$$

with coefficients

$$\begin{matrix}{b}_{0} β ( {B}_{1} + {B}_{2} ) - {B}_{2} , & ( A21a ) \\ {b}_{m} = \frac{2 ( {B}_{1} + {B}_{2} )}{m π} sin ( m β π ) . & ( A21b )\end{matrix}$$

For the limiting case as AK₀→d where d>>B and α→0, the power in the signal i(t+τ₂) at the fundamental frequency ω₀ is given by

$${P}_{0} = {( \frac{2 ( {B}_{1} + {B}_{2} )}{π} )}^{2} {sin}^{2} ( β π ) , \qquad ( A22 )$$

which for B₁=B₂=B (FIG. A6) reduces to

$${P}_{0} = {( \frac{4 B}{π} )}^{2} {sin}^{2} ( β π ) . \qquad ( A23 )$$

In a particular realization of the oN-LACE using analogue semiconductor components an input-output device characteristic of the form

i(t+τ₂)=k₁ₜₐₙₕ(k₂ν(t+τ₁)) (A24)

is achieved where k₁ and k₂ are constants. Such a characteristic is shown in FIG. A7 and has the characteristics of an almost ideal oN-LACE: the small-signal quasi-linear signal regime (SS) is approximately entirely linear, the transitional regime (T) is very narrow, and the large-signal (LS) dynamic gain is zero.

### 1.5 ‘Mode-Tracking’ Performance of the Mechanical Oscillator

In certain ‘mode-tracking’ implementations of the mechanical oscillators described by this invention, the effective resonance frequency (ERF) of the oscillator is a frequency which corresponds to a resonant mode of the mechanical structure and, through the action of the oscillator controller, the frequency corresponding to this resonant mode remains the ERF of the oscillator, even if this frequency varies. In such implementations, the oscillator controller responds to discrete or continuous changes in the frequency corresponding to the resonant mode, (such as might be brought about physical changes in the mechanical structure, or interaction between the mechanical structure and some other system), bringing about a corresponding and approximately instantaneous discrete or continuous compensating variation in the ERF of the oscillator. Such implementations find use in a wide range of instrumentation and measurement applications. For optimal mode-tracking performance, it is desirable that the amplitude control element within the oscillator controller is of the optimal type described in above. In this Section, we outline why such an oN-LACE component offers superior performance over a general non-linear amplitude control element. With reference to FIG. 5C, mode-tracking applications require that the ERF of the mechanical oscillator ω₀ is a resonance frequency of the equivalent electrical system i.e.

$${ω}_{0} = \frac{1}{\sqrt{{L}_{E} {C}_{E}}} . \qquad ( A25 )$$

Note that in mode-tracking implementations of the mechanical oscillator, it is not necessarily the case that the mechanical arrangement has a single resonance frequency. In certain applications, the mechanical arrangement may have a significant multiplicity of resonant modes, one of which it is desirable to select as the ERF of the mechanical oscillator. For any system with multiple resonant modes, an equivalent lumped electrical circuit of the form described may be defined which describes its behaviour in the region of each mode. Thus the i^{th} resonance frequency may be expressed in the form

$${ω}_{0 i} = \frac{1}{\sqrt{{L}_{Ei} {C}_{Ei}}} .$$

A stimulus of finite duration applied to the resonant system at ω₀ gives rise to a mechanical arrangement response at the same frequency which decays at a rate α_{d} determined by the system damping ratio or equivalently, the quality factor, Q. The particular implementation of the mechanical oscillator with a nominal ERF defined by (A25) and a controller including a general non-linear amplitude control element (N-LACE) of equivalent conductance G_{NL}(ν(t)) may be represented by the equivalent circuit of FIG. A1A. If a state of steady, constant amplitude oscillation of the system at ω₀ is to be attained, the N-LACE must consistently provide energy equal to that lost by virtue of the conductance G_{E} at ωₙ. This implies that if the steady-state amplitude of resonant oscillation is A₀ and—for the sake of a simple illustration—we take the linear element H to be a unity gain all-pass component (see Section 1.0), we require that (with reference to FIGS. A1A and A1B)

$$\begin{matrix}\frac{1}{2} {G}_{E} {A}_{0}^{2} = \frac{1}{T} {\int }_{0}^{T} {G}_{NL} ( v ( t ) ) {A}_{0}^{2} {sin}^{2} {ω}_{0} t d t \\ = \frac{1}{T} {\int }_{0}^{T} i ( v ( t ) ) {A}_{0} sin {ω}_{0} t d t ,\end{matrix} \qquad ( A26 )$$

where i(ν(t)) is (as previously defined), the effective feedback current.

In a general mode-tracking implementation of the mechanical oscillator, the effective voltage dependent conductance of the N-LACE may take the form of a smooth, continuous function of the excitation amplitude—such as might be described or approximated by a polynomial series:

$$\begin{matrix}{G}_{NL} ( v ) = {g}_{0} + {g}_{1} V + {g}_{2} {V}^{2} + {g}_{3} {V}^{3} + {g}_{4} {V}^{4} + … \\ i . e . & ( A27a ) \\ {G}_{NL} ( V ) = {g}_{0} + {\sum }_{i = 1}^{∞} {g}_{i} {V}^{i} & ( A27b )\end{matrix}$$

where V denotes the instantaneous magnitude of ν(t) i.e. V=|ν(t)| and for spontaneous oscillation of the closed-loop system, g₀ is necessarily a negative constant greater than G_{E}. The coefficients g, may be either positive or negative. For the amplitude control element described by (A27b) and ν(t)=A₀ sin ω₀t, the steady oscillation condition (A26) is given accordingly by

½G_{E}A₀²=½g₀A₀²+⅜g₂A₀⁴+ 5/16g₄A₀⁶+ . . . (A28)

However, in the case that the N-LACE is of the preferred, optimal type described in above (G_{oNL} in FIG. A1C), in the steady-state oscillator regime the oN-LACE output i(V,t) has a particular power-spectral density (Sections 1.2-1.4) and an amplitude that takes a value that is generally approximately independent and preferably entirely independent of V.

The input-output characteristics of a general oN-LACE are described in detail above and in the main body of the application, here—for comparison with a general non-linear amplitude control element—we consider the particular case that the input to the oN-LACE is a symmetrical, monochromatic signal at ω₀: ν(t+τ₁)=A₀ sin ω₀t and that the output of the oN-LACE, i(t+τ₂) is a square wave of amplitude B, locked in frequency and phase to ν(t+τ₁) (i.e. the positive and negative amplitude thresholds characteristic of the oN-LACE have equal magnitude: (A10) holds), the small-signal regime is characterized by a certain constant dynamic gain K₀ independent of the polarity of the signal ν(t₁+τ₁), the large-signal dynamic gain is zero and there is no transitional signal regime). In this particular case, the steady-state oscillation amplitude A₀ is found by solving:

$$\frac{1}{2} {G}_{E} {A}_{0}^{2} = \frac{1}{T} {\int }_{0}^{T} \frac{4 B}{π} {A}_{0} {sin}^{2} {ω}_{0} t d t , \qquad ( A29 )$$

thus

$${A}_{0} = \frac{4 B}{π {G}_{E}} . \qquad ( A30 )$$

In a general mode-tracking mechanical oscillator incorporating a general N-LACE such as is described by (A27b), small changes or fluctuations in the values of the coefficients g₀ and g₂ may have a profound effect on the amplitude of oscillation. As a result, such arrangements may be temperamental, and a subsidiary slow-acting amplitude control-loop may be required to promote reliable operation. This subsidiary control-loop is undesirable for several reasons—it adds complexity, it can lead to squegging and parasitic oscillation of the mechanical oscillator system and it fundamentally limits the tracking speed. This latter effect is particularly undesirable in the context of measurement applications where a fast high-resolution device demands a fast, stable control-loop.

In contrast, the oN-LACE that forms a part of the preferred embodiment of a mode-tracking implementation of the novel mechanical oscillator described—as evidenced by equation (A30)—a steady-state output that is independent of the actual negative conductance presented by the non-linearity and thus the parameters of the real devices that make up the oN-LACE. Predictable, robust performance is thus promoted without the need for any subsidiary slow-acting control-loop.

1. A mechanical oscillator arrangement comprising:
a mechanical structure including at least one transmission path therethrough and having at least one mode;
a controller including an amplifier and a feedback network configured together so as to provide a positive feedback oscillator for exciting a mode of the mechanical structure, the controller having an input and an output;
an actuator arranged to receive an output signal from the controller output and to excite a mechanical system forming part of the mechanical structure the mechanical structure based upon the controller output signal; and
a sensor in communication with the controller input, for sensing vibrations in the mechanical system and for outputting a signal related thereto, to the controller input; characterised in that:
the controller feedback network includes a non-linear amplitude control element (N-LACE), a frequency dependent gain element having an electronic transfer function, and a phase compensator.

2. The mechanical oscillator arrangement of claim 1, wherein the non-linear amplitude control element (N-LACE) has an input and an output, and wherein the N-LACE is configured to provide an output signal at the N-LACE output which has a magnitude that has a negative second derivative with respect to an input signal supplied to the N-LACE input.

3. The mechanical oscillator arrangement of claim 1, wherein the N-LACE comprises an active device with a negative differential conductance.

4. The mechanical oscillator arrangement of claim 1, wherein the N-LACE comprises a differential amplifier arranged as a long tailed pair.

5. The mechanical oscillator arrangement of claim 4, wherein the differential amplifier comprises first and second bipolar junction transistors, wherein each of the first and second bipolar junction transistors comprise:
an emitter that is connected in common to a first potential via a tail load, and
a collector that is connected to second and third potentials via first and second loads respectively, the controller amplifier output being supplied as an input to the base of the second transistor when the base of the first transistor is held at a-fixed potential.

6. The mechanical oscillator arrangement of claim 5, wherein the first load is a resistance connected between the collector of the first transistor and the second potential, wherein the second load is a resistance connected between the collector of the second transistor and the third potential; wherein the second and third potentials are the same and are provided by a common supply voltage; and wherein the controller output is coupled from the collector of the first transistor.

7. The mechanical oscillator arrangement of claim 6, wherein the transistors are each NPN bipolar junction transistors, wherein the emitters of the transistors, are connected to a negative voltage rail via the tail load, wherein the collectors of the transistors are connected to a common positive voltage rail via the first and second loads respectively, and wherein the base of the first transistor is grounded.

8. The mechanical oscillator arrangement of claim 5, wherein the tail load is variable, wherein the first load is an active load-connected between the collector of the first transistor and the second potential, and wherein the second potential is greater than the third potential to which the second transistor's collector is coupled.

9. The mechanical oscillator arrangement of claim 4, wherein the mechanical structure is arranged to generate an electrical control signal, and wherein the tail load of the long tailed pair is automatically varied by the electrical control signal.

10. The mechanical oscillator arrangement of claim 1, further comprising one or more signal processing elements positioned in one or more of the controller, the path between the controller and the actuator, and the path between the controller and the sensor, the one or more signal processing elements being configured to stabilize the positive feedback oscillator in a single operating mode.

11. The mechanical oscillator arrangement of claim 10, wherein the signal processing element(s) is/are configured
a) to provide a frequency dependent gain with a single maximum at or incorporating a selected resonant mode of the mechanical structure; and
b) to introduce a phase shift at or around the frequency of the selected resonant mode which, in combination with any other phase shifts in the controller, gives an overall loop phase shift of substantially 360n degrees, where n is an integer >=0.

12. The mechanical oscillator arrangement of claim 10, wherein the one or more signal processing elements includes a means for varying an electrical frequency dependent transfer function so as to permit switching between a first mode at a frequency f1, and at least one further mode at a different frequency f2.

13. The mechanical oscillator arrangement of claim 1, wherein the actuator and the sensor are formed as physically separate components, located at different positions relative to the mechanical system.

14. The mechanical oscillator arrangement of claim 1, further comprising signal acquisition means for acquiring and/or monitoring the signals within the arrangement.

15. The mechanical oscillator arrangement of claim 14, wherein the signal acquisition means includes at least one of a frequency counter, or a demodulator for monitoring changes in a quality factor Q of the mechanical structure.

16. The mechanical oscillator arrangement of claim 1, wherein the actuator and sensor are formed as a single transceiver.

17. The mechanical oscillator arrangement of claim 1, wherein at least one of the actuator or the sensor are moveable relative to the mechanical system so as to permit the length of the transmission path to be adjusted.

18. The mechanical oscillator arrangement of claim 1, wherein the dimensions or geometric arrangement of the mechanical structure are adjustable so as to permit the length of the transmission path to be adjusted.

19. The mechanical oscillator arrangement of claim 1, wherein the mechanical system includes a jumped mechanically resonant element.

20. The mechanical oscillator arrangement of claim 1, wherein the mechanical system includes a distributed-parameter resonant mechanical element.

21. The mechanical oscillator arrangement of claim 1, wherein:
the mechanical oscillator arrangement comprises a High Cycle Fatigue (HCF) testing apparatus; and
the mechanical structure includes a component to be tested, having a first proximal end mounted upon or within a component holder, and a second distal end; and the actuator is arranged adjacent the second distal end of the component to be tested.

22. The mechanical oscillator arrangement of claim 21, wherein the component holder is rotatable about an axis generally perpendicular to a longitudinal axis of the component to be tested.

23. The mechanical oscillator arrangement of claim 21, wherein the actuator comprises a magnet and a solenoid, wherein one of the magnet and the solenoid is mounted to the second distal end of the component to be tested, and the other of the magnet and the solenoid is fixedly mounted adjacent to the second distal end of the component to be tested so that, in use, the magnetic fields of the magnet and solenoid interact as they pass by one another when the component holder rotates.

24. The mechanical oscillator arrangement of claim 23, further comprising a means for applying a force in a direction generally parallel with a longitudinal axis of the component to be tested.

25. The mechanical oscillator arrangement of claim 24, wherein the means for applying a force in the longitudinal direction comprises a hydraulic actuator connected to the distal end of the component to be tested.

26. The mechanical oscillator arrangement of claim 21, further comprising a means for applying a compressive force to the said proximal end of the component to be tested, in the component holder.

27. The mechanical oscillator arrangement of claim 21, further comprising a means for supplying a thermal load to the said proximal end of the componentto be tested, in the component holder.

28. The mechanical oscillator arrangement of claim 1, wherein the mechanical structure includes one or more magnetic or magnetically doped or loaded micro or nano mechanical elements, directly or indirectly coupled to a standing or propagating spin-wave (magnon) within a magnetic spin system.

29. The mechanical oscillator arrangement of claim 28, wherein the magnetic spin system is a distributed parameter magnetic spin system which comprises a delay-line formed from a strip of magnetic material.

30. The mechanical oscillator arrangement of claim 29, wherein the delay-line comprises a single magnetic domain.

31. The mechanical oscillator arrangement of claim 29, wherein the delay-line comprises two or more sections of line of differing effective characteristic impedance.

32. The mechanical oscillator arrangement of claim 29, wherein the delay-line includes lumped magnetic features.

33. The mechanical oscillator arrangement of claim 29, wherein the delay-line is formed from a ferri- or ferro- magnetic material such as Yttrium Iron Garnet (YIG) or Permalloy.

34. The mechanical oscillator arrangement of claim 28, wherein the signal path around the mechanical oscillator is either partly magnetic or entirely non-magnetic.

35. The mechanical oscillator arrangement of claim 28, further comprising a means for modulating a signal at a first frequency equivalent to either of a spin-wave propagation frequency or a spin-wave excitation frequency within the magnetic spin system with a second signal which is output by the controller at a second frequency which is a resonance frequency of a micro or nano mechanical element.

36. The mechanical oscillator arrangement of claim 1, wherein the mechanical oscillator arrangement comprises a magnetic resonance tracking apparatus,
wherein the mechanical system includes one or more magnetic or magnetically doped or loaded micro or nano mechanical elements,
wherein the one or more magnetic or magnetically doped or loaded micro or nano mechanical element comprises a cantilever having a tip that is formed from or has mounted thereupon a magnetic material which magnetically couples the cantilever to a magnetic spin system, and
wherein the spin system is a lumped spin system.

37. The mechanical oscillator arrangement of claim 36, wherein the magnetic material forming or being mounted to the cantilever tip is generally spherical or conical.

38. The mechanical oscillator arrangement of claim 36, wherein the magnetic material forming or being mounted to the cantilever tip is selected from at least one of:
(a) a solid particle of hard magnetic material such as samarium cobalt, or
(b) a substrate such as silicon sputtered with a soft magnetic material such as cobalt iron.

39. The mechanical oscillator arrangement of claim 36, further comprising a means for modulating a signal at a first frequency equivalent to the Larmor frequency at which the spins in the magnetic sample precess about the external magnetic field partly or wholly generated by the magnetic material with a second signal which is output by the controller at a second frequency which is a resonance frequency of the cantilever.

40. A method of exciting a resonant mode in a mechanical system of a mechanical oscillator arrangement, comprising:
providing a positive feedback mechanical oscillator arrangement having a controller, the controller including a controller feedback network with an amplifier, a non-linear amplitude control element, a frequency dependent gain element having an electronic transfer function, and a phase compensator;
receiving a signal generated by the positive feedback oscillator at an actuator;
exciting a mechanical system having at least one resonant mode, by the actuator;
detecting vibrations in the mechanical system using a sensor in communication with the mechanical system;
generating a sensor output signal, and
feeding the sensor output signal back to the controller of the oscillator.

41. A method of tracking a resonant mode m1 in a mechanical system of a mechanical oscillator arrangement, comprising:
exciting the resonant mode m1 at a frequency f1,
causing or allowing the frequency f1 of the resonant mode to shift over time over a range of frequencies f1−df to f1+df where df<=f1/Q; and
tracking the resonant mode as it shifts over time, by configuring the frequency dependent gain element to be capable of supplying a gain and a phase shift so as to make the overall loop gain around the positive feedback oscillator unity and the loop phase shift substantially 360.n degrees, where n is an integer:>=0 over the range f1−df to f1+df.

42. A method of switching between resonant modes in a mechanical structure of a mechanical oscillator arrangement, the mechanical structure having a plurality of resonant modes, the method comprising:
exciting a first mode of the plurality of modes at a first modal frequency f1; and
moving at least one of an actuator and a sensor relative to the mechanical structure so as to cause the mechanical oscillator arrangement to excite a second resonant mode of the mechanical system at a frequency f2 different from f1.

43. A method of switching between resonant modes in a mechanical structure of a mechanical oscillator arrangement, the mechanical structure having a plurality of resonant modes, the method comprising:
exciting a first mode of the plurality of modes at a first modal frequency f1;
providing a signal processing element within the mechanical oscillator arrangement, having at least one of a frequency dependent phase shift or gain; and
adjusting the at least one of the frequency dependent phase shift or gain so as to cause the mechanical oscillator arrangement to excite a second resonant mode of the mechanical structure at a frequency f2 different from f1.

44. The method of switching of claim 42, wherein exciting the first mode of the plurality of modes comprises:
shifting the frequency f1 of the first mode over time, over a range of frequencies f1−df1 to f1+df1 where df1<=f1/01, and
tracking the first resonant mode as it shifts over time, by configuring the frequency dependent gain element to supply a gain and phase shift which makes the overall loop gain around the positive feedback oscillator unity and the loop phase shift substantially 360.n degrees, where n is an integer >=0 over the ranges of frequencies f1−df1 to f1+df1 where df1<=f1/01; and
wherein exciting the second of the plurality of modes comprises:
shifting the frequency f2 of the second mode to shift over time, over a range of frequencies f2−df2 to f2+df2 where df2<=f2/Q2, and
tracking the second resonant mode as it shifts over time, by configuring the frequency dependent gain element to supply a gain and phase shift which makes the overall loop gain around the positive feedback oscillator unity and the loop phase shift substantially 360.n degrees, where n is an integer >=0 over the ranges of frequencies f2−df2 to f2+df2 where df2<=f2/02; and
wherein (f2−f1)>>2df1; and (f2−f1)>>2df2.

45. The method of claim 40, further comprising launching both a stationary mechanical vibration and a propagating mechanical vibration into the mechanical system, a proportion of each mechanical vibration being unequal.
